(19) United States
(12) Patent Application Publication
(10) Pub. No.: US 2007/0283231 A1
(43) Pub. Date: Dec. 6, 2007

(54) Multi-Standard Scramble Code Generation Using Galois Field Arithmetic

(76) Inventor: David J. Hoyle, Sugarland, TX (US)

Correspondence Address: TEXAS INSTRUMENTS INCORPORATED, P O BOX 655474, M/S 3999, DALLAS, TX, 75265, US

(21) Appl. No.: 11/745,690

(22) Filed: May 8, 2007

Related U.S. Application Data
(60) Provisional application No. 60/746,673, filed on May 8, 2006.

(51) Int. Cl. H03M 13/00

(52) U.S. Cl. 714/781

(57) ABSTRACT

This invention is a method of using a Fibonacci form linear feedback shift register. The Fibonacci form linear feedback shift register having an initial state and a set of taps is converter into an equivalent Galois form linear feedback shift register. The Galois form linear feedback shift register state is altered employing Galois field arithmetic. The altered Galois form linear feedback shift register is converted into an equivalent altered Fibonacci form linear feedback shift register. A pseudo-random number produced by the altered Fibonacci form linear feedback shift register is used, for example in a scramble code.

### CLAIM OF PRIORITY

This application claims priority under 35 U.S.C. 119(e)(1) to U.S. Provisional Application No. 60/746,673 filed May 8, 2006.

### TECHNICAL FIELD OF THE INVENTION

The technical field of this invention is linear feedback shift register used to generate code sequences.

### BACKGROUND OF THE INVENTION

Generating parallel blocks of the scramble code sequences using minimal storage, hardware allows for general purpose solutions. The cost of the new generator has the same storage requirements for all codes for all standards and is of order O(n). This is not the case with current methods which have storage requirements of the order O(n³). The solution allows software based scramble code generators to be used for more generally programmable solutions for multiple standards. Currently they are designed for fixed purposes such as CDMA2000 or 3GPP up or down link. Also in the case of masked generators such as CDMA2000 long codes a mask is needed that collapses the state down to a single bit for each clock. This requires extra hardware. The method converts the mask to a constant known offset allowing the standard new solution to be used for parallel output generation.

### SUMMARY OF THE INVENTION

There is a direct link between a Fibonacci based generator and a Galois generator. This link maps the states between the 2 machines. The Galois state cannot be used directly for parallel bit generation but the mapping allows this. The Galois machine can be advanced in logarithmic time to a required point. Mapping from the code to a table allows an arbitrary mask to be converted to a constant coefficient. A reverse mapping has also been found and an algorithm for its calculation. This allows the initial state to be found for a Galois based generator using the Fibonacci state.

This method does not use a mechanical hardware matrix generator it uses Galois field multipliers and adders which are very compact in hardware. It uses minimal storage and one implementation can serve many standards at no extra cost.

This method is general purpose and allows easy software implementation on any processor previous methods are bit based and do not allow efficient parallel data path implementation which what processors use. They are also specialized to particular standards due to the high cost of the matrices, which are sparse but random.

### BRIEF DESCRIPTION OF THE DRAWINGS

These and other aspects of this invention are illustrated in the drawings, in which:

FIG. 1 illustrates the organization of a typical digital signal processor to which this invention is applicable (prior art);

FIG. 2 illustrates details of a very long instruction word digital signal processor core suitable for use in FIG. 1 (prior art);

FIG. 3 illustrates the pipeline stages of the very long instruction word digital signal processor core illustrated in FIG. 2 (prior art);

FIG. 4 illustrates the instruction syntax of the very long instruction word digital signal processor core illustrated in FIG. 2 (prior art);

FIG. 5 illustrates a prior art implementation of a linear feedback shift register sequence pseudo-noise generator called the Fibonacci form;

FIG. 6 illustrates a prior art alternative form linear feedback shift register called the Galois form;

FIG. 7 illustrates an example use of this invention;

FIG. 8 illustrates the operation of a prior art Galois field multiply instruction;

FIG. 9 illustrates the definitions of control register fields used in the instruction of FIG. 8 (prior art);

FIG. 10 illustrates an example linear feedback shift register form of the scramble code generator according to the prior art;

FIG. 11 illustrates an embodiment of this invention using a mask register;

FIG. 12 illustrates another example linear feedback shift register form of the scramble code generator according to the prior art; and

FIG. 13 illustrates the steps of practicing one embodiment of this invention.

### DETAILED DESCRIPTION OF PREFERRED EMBODIMENTS

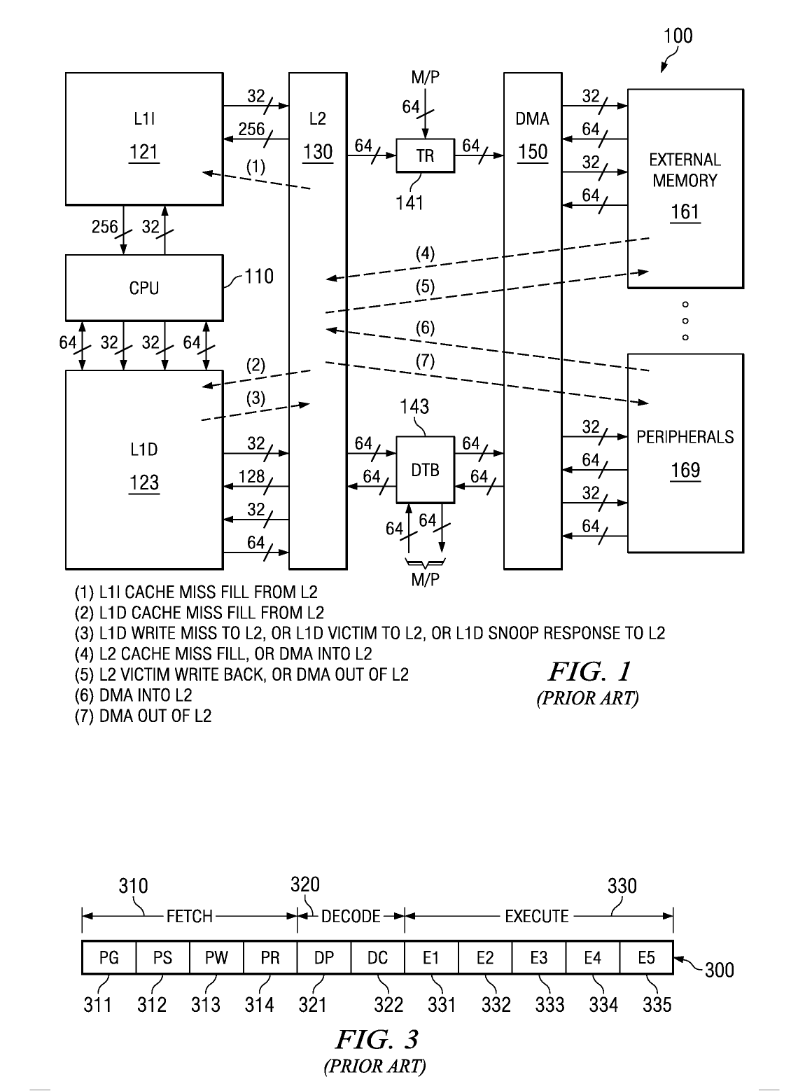

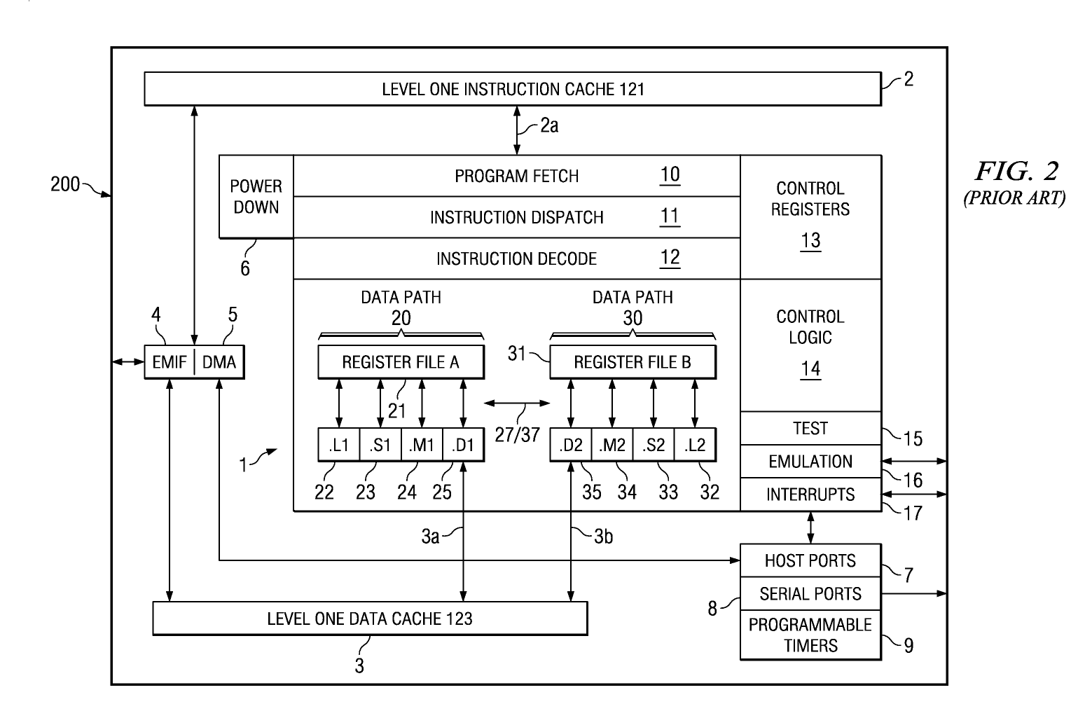

FIG. 1 illustrates the organization of a typical digital signal processor system 100 to which this invention is applicable (prior art). Digital signal processor system 100 includes central processing unit core 110. Central processing unit core 110 includes the data processing portion of digital signal processor system 100. Central processing unit core 110 could be constructed as known in the art and would typically includes a register file, an integer arithmetic logic unit, an integer multiplier and program flow control units. An example of an appropriate central processing unit core is described below in conjunction with FIGS. 2 to 4.

Digital signal processor system 100 includes a number of cache memories. FIG. 1 illustrates a pair of first level caches. Level one instruction cache (L1I) 121 stores instructions used by central processing unit core 110. Central processing unit core 110 first attempts to access any instruction from level one instruction cache 121. Level one data cache (L1D) 123 stores data used by central processing unit core 110. Central processing unit core 110 first attempts to access any required data from level one data cache 123. The two level one caches are backed by a level two unified cache (L2) 130. In the event of a cache miss to level one instruction cache 121 or to level one data cache 123, the requested instruction or data is sought from level two unified cache 130. If the requested instruction or data is stored in level two unified cache 130, then it is supplied to the requesting level one cache for supply to central processing unit core 110. As is known in the art, the requested instruction or data may be simultaneously supplied to both the requesting cache and central processing unit core 110 to speed use.

Level two unified cache 130 is further coupled to higher level memory systems. Digital signal processor system 100 may be a part of a multiprocessor system. The other processors of the multiprocessor system are coupled to level two unified cache 130 via a transfer request bus 141 and a data transfer bus 143. A direct memory access unit 150 provides the connection of digital signal processor system 100 to external memory 161 and external peripherals 169.

FIG. 2 is a block diagram illustrating details of a digital signal processor integrated circuit 200 suitable but not essential for use in this invention (prior art). The digital signal processor integrated circuit 200 includes central processing unit 1, which is a 32-bit eight-way VLIW pipelined processor. Central processing unit 1 is coupled to level 1 instruction cache 121 included in digital signal processor integrated circuit 200. Digital signal processor integrated circuit 200 also includes level one data cache 123. Digital signal processor integrated circuit 200 also includes peripherals 4 to 9. These peripherals preferably include an external memory interface (EMIF) 4 and a direct memory access (DMA) controller 5. External memory interface (EMIF) 4 preferably supports access to supports synchronous and asynchronous SRAM and synchronous DRAM. Direct memory access (DMA) controller 5 preferably provides 2-channel auto-boot loading direct memory access. These peripherals include power-down logic 6. Power-down logic 6 preferably can halt central processing unit activity, peripheral activity, and phase lock loop (PLL) clock synchronization activity to reduce power consumption. These peripherals also include host ports 7, serial ports 8 and programmable timers 9.

Central processing unit 1 has a 32-bit, byte addressable address space. Internal memory on the same integrated circuit is preferably organized in a data space including level one data cache 123 and a program space including level one instruction cache 121. When off-chip memory is used, preferably these two spaces are unified into a single memory space via the external memory interface (EMIF) 4.

Level one data cache 123 may be internally accessed by central processing unit 1 via two internal ports 3a and 3b. Each internal port 3a and 3b preferably has 32 bits of data and a 32-bit byte address reach. Level one instruction cache 121 may be internally accessed by central processing unit 1 via a single port 2a. Port 2a of level one instruction cache 121 preferably has an instruction-fetch width of 256 bits and a 30-bit word (four bytes) address, equivalent to a 32-bit byte address.

Central processing unit 1 includes program fetch unit 10, instruction dispatch unit 11, instruction decode unit 12 and two data paths 20 and 30. First data path 20 includes four functional units designated L1 unit 22, S1 unit 23, M1 unit 24 and D1 unit 25 and 16 32-bit A registers forming register file 21. Second data path 30 likewise includes four functional units designated L2 unit 32, S2 unit 33, M2 unit 34 and D2 unit 35 and 16 32-bit B registers forming register file 31. The functional units of each data path access the corresponding register file for their operands. There are two cross paths 27 and 37 permitting access to one register in the opposite register file each pipeline stage. Central processing unit 1 includes control registers 13, control logic 14, and test logic 15, emulation logic 16 and interrupt logic 17.

Program fetch unit 10, instruction dispatch unit 11 and instruction decode unit 12 recall instructions from level one instruction cache 121 and deliver up to eight 32-bit instructions to the functional units every instruction cycle.

Processing occurs in each of the two data paths 20 and 30. As previously described above each data path has four corresponding functional units (L, S, M and D) and a corresponding register file containing 16 32-bit registers. Each functional unit is controlled by a 32-bit instruction. The data paths are further described below. A control register file 13 provides the means to configure and control various processor operations.

FIG. 3 illustrates the pipeline stages 300 of digital signal processor core 110 (prior art). These pipeline stages are divided into three groups: fetch group 310; decode group 320; and execute group 330. All instructions in the instruction set flow through the fetch, decode, and execute stages of the pipeline. Fetch group 310 has four phases for all instructions, and decode group 320 has two phases for all instructions. Execute group 330 requires a varying number of phases depending on the type of instruction.

The fetch phases of the fetch group 310 are: Program address generate phase 311 (PG); Program address send phase 312 (PS); Program access ready wait stage 313 (PW); and Program fetch packet receive stage 314 (PR). Digital signal processor core 110 uses a fetch packet (FP) of eight instructions. All eight of the instructions proceed through fetch group 310 together. During PG phase 311, the program address is generated in program fetch unit 10. During PS phase 312, this program address is sent to memory. During PW phase 313, the memory read occurs. Finally during PR phase 314, the fetch packet is received at CPU 1.

The decode phases of decode group 320 are: Instruction dispatch (DP) 321; and Instruction decode (DC) 322. During the DP phase 321, the fetch packets are split into execute packets. Execute packets consist of one or more instructions which are coded to execute in parallel. During DP phase 322, the instructions in an execute packet are assigned to the appropriate functional units. Also during DC phase 322, the source registers, destination registers and associated paths are decoded for the execution of the instructions in the respective functional units.

The execute phases of the execute group 330 are: Execute 1 (E1) 331; Execute 2 (E2) 332; Execute 3 (E3) 333; Execute 4 (E4) 334; and Execute 5 (E5) 335. Different types of instructions require different numbers of these phases to complete. These phases of the pipeline play an important role in understanding the device state at CPU cycle boundaries.

During E1 phase 331, the conditions for the instructions are evaluated and operands are read for all instruction types. For load and store instructions, address generation is performed and address modifications are written to a register file. For branch instructions, branch fetch packet in PG phase 311 is affected. For all single-cycle instructions, the results are written to a register file. All single-cycle instructions complete during the E1 phase 331.

During the E2 phase 332, for load instructions, the address is sent to memory. For store instructions, the address and data are sent to memory. Single-cycle instructions that saturate results set the SAT bit in the control status register (CSR) if saturation occurs. For single cycle 16 by 16 multiply instructions, the results are written to a register file. For M unit non-multiply instructions, the results are written to a register file. All ordinary multiply unit instructions complete during E2 phase 322.

During E3 phase 333, data memory accesses are performed. Any multiply instruction that saturates results sets the SAT bit in the control status register (CSR) if saturation occurs. Store instructions complete during the E3 phase 333.

During E4 phase 334, for load instructions, data is brought to the CPU boundary. For multiply extensions instructions, the results are written to a register file. Multiply extension instructions complete during the E4 phase 334.

During E5 phase 335, load instructions write data into a register. Load instructions complete during the E5 phase 335.

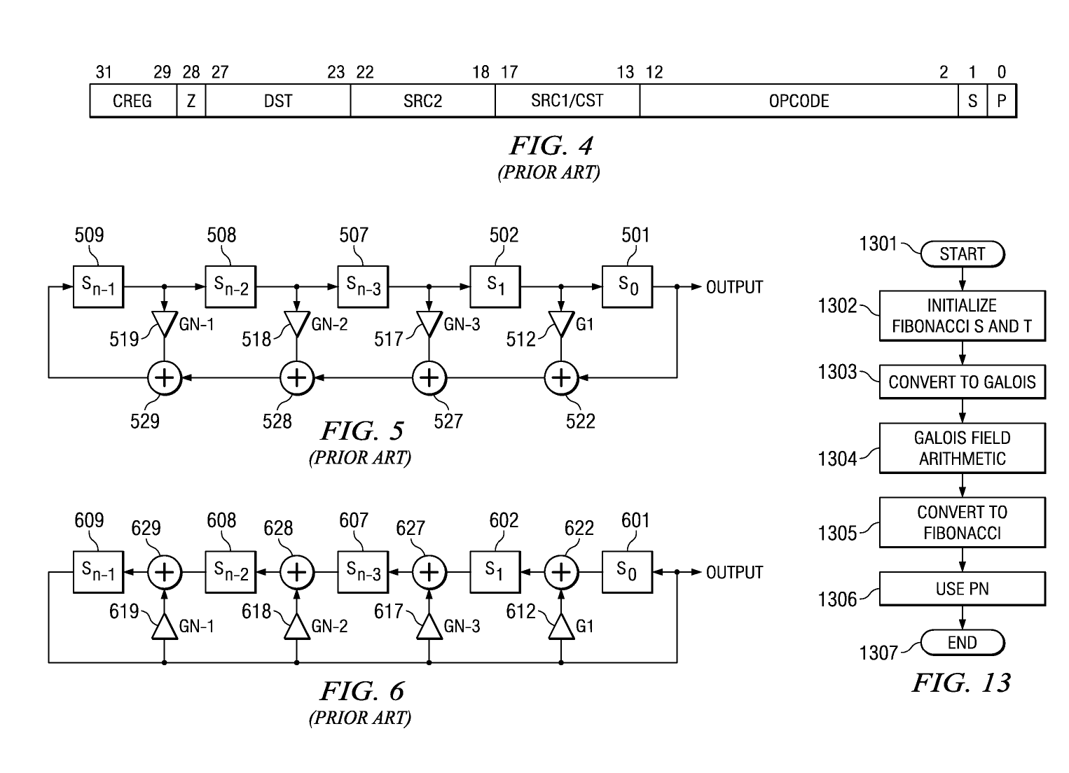

FIG. 4 illustrates an example of the instruction coding of instructions used by digital signal processor core 110 (prior art). Each instruction consists of 32 bits and controls the operation of one of the eight functional units. The bit fields are defined as follows. The creg field (bits 29 to 31) is the conditional register field. These bits identify whether the instruction is conditional and identify the predicate register. The z bit (bit 28) indicates whether the predication is based upon zero or not zero in the predicate register. If z=1, the test is for equality with zero. If z=0, the test is for nonzero. The case of creg=0 and z=0 is treated as always true to allow unconditional instruction execution. The creg field is encoded in the instruction opcode as shown in Table 1.

TABLE 1

| Conditional | creg | | | z |
|---|---|---|---|---|
| Register | 31 | 30 | 29 | 28 |
| Unconditional | 0 | 0 | 0 | 0 |
| Reserved | 0 | 0 | 0 | 1 |
| B0 | 0 | 0 | 1 | z |
| B1 | 0 | 1 | 0 | z |
| B2 | 0 | 1 | 1 | z |
| A1 | 1 | 0 | 0 | z |
| A2 | 1 | 0 | 1 | z |
| A0 | 1 | 1 | 0 | z |
| Reserved | 1 | 1 | 1 | x |

Note that “z” in the z bit column refers to the zero/not zero comparison selection noted above and “x” is a don't care state. This coding can only specify a subset of the 32 registers in each register file as predicate registers. This selection was made to preserve bits in the instruction coding.

The dst field (bits 23 to 27) specifies one of the 32 registers in the corresponding register file as the destination of the instruction results.

The scr2 field (bits 18 to 22) specifies one of the 32 registers in the corresponding register file as the second source operand.

The scr1/cst field (bits 13 to 17) has several meanings depending on the instruction opcode field (bits 3 to 12). The first meaning specifies one of the 32 registers of the corresponding register file as the first operand. The second meaning is a 5-bit immediate constant. Depending on the instruction type, this is treated as an unsigned integer and zero extended to 32 bits or is treated as a signed integer and sign extended to 32 bits. Lastly, this field can specify one of the 32 registers in the opposite register file if the instruction invokes one of the register file cross paths 27 or 37.

The opcode field (bits 3 to 12) specifies the type of instruction and designates appropriate instruction options. A detailed explanation of this field is beyond the scope of this invention except for the instruction options detailed below.

The s bit (bit 1) designates the data path 20 or 30. If s=0, then data path 20 is selected. This limits the functional unit to L1 unit 22, S1 unit 23, M1 unit 24 and D1 unit 25 and the corresponding register file A 21. Similarly, s=1 selects data path 20 limiting the functional unit to L2 unit 32, S2 unit 33, M2 unit 34 and D2 unit 35 and the corresponding register file B 31.

The p bit (bit 0) marks the execute packets. The p-bit determines whether the instruction executes in parallel with the following instruction. The p-bits are scanned from lower to higher address. If p=1 for the current instruction, then the next instruction executes in parallel with the current instruction. If p=0 for the current instruction, then the next instruction executes in the cycle after the current instruction. All instructions executing in parallel constitute an execute packet. An execute packet can contain up to eight instructions. Each instruction in an execute packet must use a different functional unit.

In third generation wireless systems such as 3GPP, CDMA2000, IS2000 the symbol data generated for channel coding is further spread using orthogonal spreading codes such as Walsh codes. These spread the signal to the transmission rate from a factor of 4 to a factor of 512. After spreading, some form of scrambling takes place. This has no effect on the bandwidth but minimizes the peak to average ratio, so that power amplifiers in the system operate closer to their efficiency point. This scramble code is assumed to be very long and cannot be stored in a memory. Thus it has to be generated as needed. The starting phase of this sequence is also a variable and so to generate the sequence on the right phase requires some way of mapping the phase to the actual initial seed of the generator.

Generators are based on the linear feedback shift register (LFSR). Several techniques are used to generate the state of the machine for a particular phase. It is often required to generate several bits of the sequence at once as uplink receiver structures typically use massively parallel architectures. This invention allows both general purpose generation for multiple standards and codes and parallel generation of the bits combined with low data storage.

The suggested architecture provides these common benefits for less total area than a conventional design. This invention permits: parallel generation of bits; multi-standard support for small incremental cost; support of long code generation using arbitrary masks; lower memory cost than previous methods; lower gate count due to using efficient Galois field multiplier rather than power matrix method; and lower gate count due to encoding of the seed.

FIG. 5 illustrates a prior art implementation of a LFSR sequence pseudo-noise generator. This structure is often used in the various standards such as 3GPP. FIG. 5 illustrates a feed forward register architecture the Fibonacci form. This generator operates analogously to the Fibonacci series in which F_{N}=F_{N-1}+F_{N-2}.

The Fibonacci form LFSR includes plural 1-bit state registers 501 to 509. Each operational cycle the state of state register S_{M} passes to the next state register S_{M-1}. The output of the LFSR generator is taken from the state register S₀ 501. The feed forward is performed by selecting taps according to a polynomial generator. The tap weights g₁ 512 to g_{N-1} 519 determine the feed forward. Each tap weight can be 0 or 1. If 0, then there is no feed forward at that tap. If 1, then the value of the state register is part of the feed forward. Note that there is no tap weight g₀. In effect g₀ is always 1. Otherwise the LFSR would be at least one bit shorter. The set of exclusive OR gates 521 to 529 combines all the taps and supplies the input to state register S_{N-1} 509.

The convention adopted for the initial state S and the polynomial generator T are as follows. The

$$S = [ \begin{matrix}{S}_{0} \\ {S}_{1} \\ ⋮ \\ {S}_{\overline{N} 1}\end{matrix} ]$$

is the state vector of the pseudo-noise (PN) generator.

$$T = [ \begin{matrix}{g}_{0} \\ {g}_{1} \\ ⋮ \\ {g}_{N - 1}\end{matrix} ]$$

is the tap weight vector of the pseudo-noise generator.

The LFSR sequences of most practical importance are called maximal length. A maximal length is a sequence generated by an LFSR with an N state shift register has a periodicity 2^{N-1}. An LFSR that generates a maximal length sequence will be termed a maximal length LFSR. Maximal length LFSR sequences are also called m-sequences. For a given N, an LFSR with a proper choice of the taps Tᵢ will result in a maximal length sequence.

The tap vector T represents the feed forward path connections. Using the conventions above described, the pseudo-noise generator operation can be modeled in a state transition matrix formulation as follows:
where: M⁽¹⁾ is the N by N binary-valued matrix representing the shift register. The matrix operations are in GF(2). The transition state matrix M⁽¹⁾ is built as follows:

$${M}^{( 1 )} = [ \begin{matrix}0 & 1 & 0 & 0 & … & 0 \\ 0 & 0 & 1 & 0 & … & 0 \\ 0 & 0 & 0 & 1 & … & 0 \\ ⋮ & ⋮ & ⋮ & ⋮ & ⋰ & ⋮ \\ 0 & 0 & 0 & 0 & … & 1 \\ {g}_{0} & {g}_{1} & {g}_{2} & {g}_{3} & … & {g}_{N - 1}\end{matrix} ] \qquad ( 2 )$$

By substitution equation (1) becomes:

$${S}^{( 1 )} = [ \begin{matrix}{S}_{0}^{( 1 )} \\ {S}_{1}^{( 1 )} \\ {S}_{2}^{( 1 )} \\ {S}_{3}^{( 1 )} \\ ⋮ \\ {S}_{N - 1}^{( 1 )}\end{matrix} ] = [ \begin{matrix}0 & 1 & 0 & 0 & … & 0 \\ 0 & 0 & 1 & 0 & … & 0 \\ 0 & 0 & 0 & 1 & … & 0 \\ ⋮ & ⋮ & ⋮ & ⋮ & ⋰ & ⋮ \\ 0 & 0 & 0 & 0 & … & 1 \\ {g}_{0} & {g}_{1} & {g}_{2} & {g}_{3} & … & {g}_{N - 1}\end{matrix} ] \cdot [ \begin{matrix}{S}_{0}^{( 0 )} \\ {S}_{1}^{( 0 )} \\ {S}_{2}^{( 0 )} \\ {S}_{3}^{( 0 )} \\ ⋮ \\ {S}_{N - 1}^{( 0 )}\end{matrix} ] = {M}^{( 1 )} {S}^{( 0 )} \qquad ( 3 )$$

Equations (1) and (3) give the state vector at cycle 1 given the initial state at cycle 0 and the state transition matrix. In general:

$${S}^{( k )} = {M}^{( k )} {S}^{( 0 )} , {M}^{( k )} = \underbrace{{M}^{( 1 )} \cdot {M}^{( 1 )} \cdot … \cdot {M}^{( 1 )}}_{k elements} = {( {M}^{( 1 )} )}^{k} \qquad ( 4 )$$

Equation (4) shows a way to generate any state and thus N consecutive chips of the sequence at offset k given the initial state. This is a very direct, mechanical method to generate the state of the Fibonacci generator for any arbitrary time offset. For a particular set of feed forward taps chosen the matrix M is very sparse as are its powers. Thus a dedicated circuit for a particular polynomial optimizes to a compact solution. The output is taken from state bit 0 as in equation (5).

$$FibonacciOutput ( i ) = [ \begin{matrix}1 & 0 & 0 & 0 & 0 & ⋮ & 0 ] \cdot \end{matrix} [ \begin{matrix}{S}_{0}^{( 0 )} \\ {S}_{1}^{( 0 )} \\ {S}_{2}^{( 0 )} \\ {S}_{3}^{( 0 )} \\ ⋮ \\ {S}_{N - 1}^{( 0 )}\end{matrix} ] = {V}_{f}^{T} \cdot {S}^{( 0 )} \qquad ( 5 )$$

A Fibonacci machine is used because it generates bits in parallel and a sequence of bits can be taken from the state. Thus the state contains the future N bits from the last N stages.

However when different polynomials are required, for example to support different standards, the arbitrary matrices need to be programmable. In the case of one of the 3GPP uplink polynomials, this would require, 25 by 25 by 25 bits, or 488 32 bit words. This is an expensive solution because each bit would need a storage register. The Fibonacci generator cannot be advanced without using the power matrices by an arbitrary amount and this is an expensive solution when needed for general purpose use in multiple standards.

This prior art allows multiple bits to be generated at once. According to this prior art it is necessary to map the code to its Fibonacci form to generate the future bits. The disadvantage of the power matrix form is the memory required to store the feed forward matrices for a general purpose polynomial is very large on the order of N³ bits. This invention has the advantage that for arbitrary polynomials the memory cost is only 2N bits.

FIG. 6 illustrates an alternative form LFSR called the Galois form. The Galois form LFSR includes plural 1-bit state registers 601 to 609. Each operational cycle the state of state register S_{M} passes to a next state register S_{M+1}. The state of the supplying state register is combined via exclusive OR gates 622 to 629 with data from state register Sₒ 601 controlled by corresponding tap weights g₁ 612 to g_{N-1} 619. The Galois form illustrated in FIG. 6 differs from the Fibonacci form illustrated in FIG. 5 as follows. The exclusive OR operations are inserted within the LFSR delay line. In addition the movement of state values is in the opposite direction in the Galois form. As we will show later, for maximal length LFSR sequences, the Fibonacci and the Galois forms produce identical pseudo-noise sequences except for a constant time shift.

A system based on Galois field arithmetic would be much more efficient in terms of storage for the general case and be accessible to arithmetic speedup methods. In particular, Galois field arithmetic is more easily accomplished than the matrix operations described above in the Fibonacci form. This invention uses mapping that allows a Galois generator to be used in the form of a multiplicative field in GF(2^{N}). The bits in the element in this field are mapped to the equivalent Fibonacci machine state at that time. This invention is: programmable with little storage needs for different standards; requires the same or less hardware for the special case; and lends itself to efficient software implementation

Prior art teaching enable mapping the Galois form of FIG. 6 to the Fibonacci form of FIG. 5. The Fibonacci form of FIG. 5 and the Galois form of FIG. 6 are mirror images of each other. A feed forward Fibonacci tap becomes a feed back tap in the Galois form. The coefficients g₁ and gₘ are 1 by definition.

The data flows through each structure in opposite directions. The output of the Galois machine is the input to state bit 0 and the output of state bit n−1 via the feed back. The output of the Fibonacci machine is the output of state bit 0.

The construction of the Fibonacci machine illustrated in FIG. 5 has its own equivalent state update matrix. The Galois machine is the transpose of the Fibonacci machine. The difference between these machines is in the definition of the state. The Galois machine form of equation (3) is:

$${S}^{( 1 )} = [ \begin{matrix}{S}_{0}^{( 1 )} \\ {S}_{1}^{( 1 )} \\ {S}_{2}^{( 1 )} \\ {S}_{3}^{( 1 )} \\ ⋮ \\ {S}_{N - 1}^{( 1 )}\end{matrix} ] = [ \begin{matrix}0 & 0 & 0 & 0 & … & {g}_{0} \\ 1 & 0 & 0 & 0 & … & {g}_{1} \\ 0 & 1 & 0 & 0 & … & {g}_{2} \\ ⋮ & ⋮ & ⋮ & ⋮ & ⋰ & ⋮ \\ 0 & 0 & 0 & 0 & … & {g}_{N - 2} \\ 0 & 0 & 0 & 0 & … & {g}_{N - 1}\end{matrix} ] \cdot [ \begin{matrix}{S}_{0}^{( 0 )} \\ {S}_{1}^{( 0 )} \\ {S}_{2}^{( 0 )} \\ {S}_{3}^{( 0 )} \\ ⋮ \\ {S}_{N - 1}^{( 0 )}\end{matrix} ] = {M}^{( 1 )} {S}^{( 0 )} \qquad ( 6 )$$

The output bit equation corresponding to equation (5) is:

$$GaloisOutput ( i ) = [ \begin{matrix}0 & 0 & 0 & 0 & 0 & ⋮ & 1 ] \cdot \end{matrix} [ \begin{matrix}{S}_{0}^{( 0 )} \\ {S}_{1}^{( 0 )} \\ {S}_{2}^{( 0 )} \\ {S}_{3}^{( 0 )} \\ ⋮ \\ {S}_{N - 1}^{( 0 )}\end{matrix} ] = {V}_{g}^{T} \cdot {S}^{( 0 )} \qquad ( 7 )$$

The sequence of states that the Galois machine goes through after each clock is equivalent to a finite multiplicative field generated for GF(2^{N}) over the polynomial g. The elements of g are the tap connections of the LFSR. Multiplication by α in GF(2^{N}) can be seen to be equivalent to the state machine being clocked as the whole state is added to the current state if the bit about to be shifted out is 1. By a process of induction any number of clocks can be translated into a multiplication by αⁱ: where α is the primitive element of the field.

N is the number of bits in the state and the generator polynomial is the feedback tap polynomial. Galois field multiplication is a polynomial product of 2 numbers in the field followed by a polynomial division by the generator polynomial, with the remainder being the result. In a manner analogous to multiplying powers of the state transition matrix to get arbitrary offsets from zero time, multiplying by powers of α will also yield the desired state.

The output bits of the Fibonacci and the Galois structures are identical assuming the correct initial state. The Galois sequence is equivalent to the Fibonacci sequence though there is a time offset between them and the order of the bits in the shift register state is also different. The two state sequences generated by the two structures can be mapped to each other for the desired result. Thus for an arbitrary set of bits of a state in G all of the same bits in F can be reproduced using a fixed linear mapping function. The previously unknown time offset between Galois and Fibonacci machines is also shown as:
S_{F}=f(S_{G}) (8)
This mapping is reversible and linear, allowing the Galois state to be computed from the Fibonacci state.

The following is an example employing one of the scramble codes used in the downlink in the 3GPP specification. This has generator polynomial G=X¹⁸+X¹⁰+X⁷+X⁵+1. This is an 18 bit shift register. Table 1 shows the Fibonacci sequence for the first 32 values.

TABLE 1

| | S0 | S1 | S2 | S3 | S4 | S5 | S6 | S7 | S8 | S9 | S10 | S11 | S12 | S13 | S14 | S15 | S16 | S17 |
|---|---|---|---|---|---|---|---|---|---|---|---|---|---|---|---|---|---|---|
| 0 | 0 | 0 | 0 | 0 | 0 | 0 | 0 | 0 | 0 | 0 | 0 | 0 | 0 | 0 | 0 | 0 | 0 | 1 |
| 1 | 0 | 0 | 0 | 0 | 0 | 0 | 0 | 0 | 0 | 0 | 0 | 0 | 0 | 0 | 0 | 0 | 1 | 0 |
| 2 | 0 | 0 | 0 | 0 | 0 | 0 | 0 | 0 | 0 | 0 | 0 | 0 | 0 | 0 | 0 | 1 | 0 | 0 |
| 3 | 0 | 0 | 0 | 0 | 0 | 0 | 0 | 0 | 0 | 0 | 0 | 0 | 0 | 0 | 1 | 0 | 0 | 0 |
| 4 | 0 | 0 | 0 | 0 | 0 | 0 | 0 | 0 | 0 | 0 | 0 | 0 | 0 | 1 | 0 | 0 | 0 | 0 |
| 5 | 0 | 0 | 0 | 0 | 0 | 0 | 0 | 0 | 0 | 0 | 0 | 0 | 1 | 0 | 0 | 0 | 0 | 0 |
| 6 | 0 | 0 | 0 | 0 | 0 | 0 | 0 | 0 | 0 | 0 | 0 | 1 | 0 | 0 | 0 | 0 | 0 | 0 |
| 7 | 0 | 0 | 0 | 0 | 0 | 0 | 0 | 0 | 0 | 0 | 1 | 0 | 0 | 0 | 0 | 0 | 0 | 0 |
| 8 | 0 | 0 | 0 | 0 | 0 | 0 | 0 | 0 | 0 | 1 | 0 | 0 | 0 | 0 | 0 | 0 | 0 | 1 |
| 9 | 0 | 0 | 0 | 0 | 0 | 0 | 0 | 0 | 1 | 0 | 0 | 0 | 0 | 0 | 0 | 0 | 1 | 0 |
| 10 | 0 | 0 | 0 | 0 | 0 | 0 | 0 | 1 | 0 | 0 | 0 | 0 | 0 | 0 | 0 | 1 | 0 | 0 |
| 11 | 0 | 0 | 0 | 0 | 0 | 0 | 1 | 0 | 0 | 0 | 0 | 0 | 0 | 0 | 1 | 0 | 0 | 1 |
| 12 | 0 | 0 | 0 | 0 | 0 | 1 | 0 | 0 | 0 | 0 | 0 | 0 | 0 | 1 | 0 | 0 | 1 | 0 |
| 13 | 0 | 0 | 0 | 0 | 1 | 0 | 0 | 0 | 0 | 0 | 0 | 0 | 1 | 0 | 0 | 1 | 0 | 1 |
| 14 | 0 | 0 | 0 | 1 | 0 | 0 | 0 | 0 | 0 | 0 | 0 | 1 | 0 | 0 | 1 | 0 | 1 | 0 |
| 15 | 0 | 0 | 1 | 0 | 0 | 0 | 0 | 0 | 0 | 0 | 1 | 0 | 0 | 1 | 0 | 1 | 0 | 0 |
| 16 | 0 | 1 | 0 | 0 | 0 | 0 | 0 | 0 | 0 | 1 | 0 | 0 | 1 | 0 | 1 | 0 | 0 | 1 |
| 17 | 1 | 0 | 0 | 0 | 0 | 0 | 0 | 0 | 1 | 0 | 0 | 1 | 0 | 1 | 0 | 0 | 1 | 0 |
| 18 | 0 | 0 | 0 | 0 | 0 | 0 | 0 | 1 | 0 | 0 | 1 | 0 | 1 | 0 | 0 | 1 | 0 | 1 |
| 19 | 0 | 0 | 0 | 0 | 0 | 0 | 1 | 0 | 0 | 1 | 0 | 1 | 0 | 0 | 1 | 0 | 1 | 0 |
| 20 | 0 | 0 | 0 | 0 | 0 | 1 | 0 | 0 | 1 | 0 | 1 | 0 | 0 | 1 | 0 | 1 | 0 | 0 |
| 21 | 0 | 0 | 0 | 0 | 1 | 0 | 0 | 1 | 0 | 1 | 0 | 0 | 1 | 0 | 1 | 0 | 0 | 0 |
| 22 | 0 | 0 | 0 | 1 | 0 | 0 | 1 | 0 | 1 | 0 | 0 | 1 | 0 | 1 | 0 | 0 | 0 | 1 |
| 23 | 0 | 0 | 1 | 0 | 0 | 1 | 0 | 1 | 0 | 0 | 1 | 0 | 1 | 0 | 0 | 0 | 1 | 0 |
| 24 | 0 | 1 | 0 | 0 | 1 | 0 | 1 | 0 | 0 | 1 | 0 | 1 | 0 | 0 | 0 | 1 | 0 | 1 |
| 25 | 1 | 0 | 0 | 1 | 0 | 1 | 0 | 0 | 1 | 0 | 1 | 0 | 0 | 0 | 1 | 0 | 1 | 0 |
| 26 | 0 | 0 | 1 | 0 | 1 | 0 | 0 | 1 | 0 | 1 | 0 | 0 | 0 | 1 | 0 | 1 | 0 | 1 |
| 27 | 0 | 1 | 0 | 1 | 0 | 0 | 1 | 0 | 1 | 0 | 0 | 0 | 1 | 0 | 1 | 0 | 1 | 1 |
| 28 | 1 | 0 | 1 | 0 | 0 | 1 | 0 | 1 | 0 | 0 | 0 | 1 | 0 | 1 | 0 | 1 | 1 | 0 |
| 29 | 0 | 1 | 0 | 0 | 1 | 0 | 1 | 0 | 0 | 0 | 1 | 0 | 1 | 0 | 1 | 1 | 0 | 1 |
| 30 | 1 | 0 | 0 | 1 | 0 | 1 | 0 | 0 | 0 | 1 | 0 | 1 | 0 | 1 | 1 | 0 | 1 | 1 |
| 31 | 0 | 0 | 1 | 0 | 1 | 0 | 0 | 0 | 1 | 0 | 1 | 0 | 1 | 1 | 0 | 1 | 1 | 0 |

Table 2 shows the equivalent sequence of Galois numbers.

TABLE 2

| | S0 | S1 | S2 | S3 | S4 | S5 | S6 | S7 | S8 | S9 | S10 | S11 | S12 | S13 | S14 | S15 | S16 | S17 |
|---|---|---|---|---|---|---|---|---|---|---|---|---|---|---|---|---|---|---|
| 0 | 1 | 0 | 0 | 0 | 0 | 0 | 0 | 0 | 0 | 0 | 0 | 0 | 0 | 0 | 0 | 0 | 0 | 0 |
| 1 | 0 | 1 | 0 | 0 | 0 | 0 | 0 | 0 | 0 | 0 | 0 | 0 | 0 | 0 | 0 | 0 | 0 | 0 |
| 2 | 0 | 0 | 1 | 0 | 0 | 0 | 0 | 0 | 0 | 0 | 0 | 0 | 0 | 0 | 0 | 0 | 0 | 0 |
| 3 | 0 | 0 | 0 | 1 | 0 | 0 | 0 | 0 | 0 | 0 | 0 | 0 | 0 | 0 | 0 | 0 | 0 | 0 |
| 4 | 0 | 0 | 0 | 0 | 1 | 0 | 0 | 0 | 0 | 0 | 0 | 0 | 0 | 0 | 0 | 0 | 0 | 0 |
| 5 | 0 | 0 | 0 | 0 | 0 | 1 | 0 | 0 | 0 | 0 | 0 | 0 | 0 | 0 | 0 | 0 | 0 | 0 |
| 6 | 0 | 0 | 0 | 0 | 0 | 0 | 1 | 0 | 0 | 0 | 0 | 0 | 0 | 0 | 0 | 0 | 0 | 0 |
| 7 | 0 | 0 | 0 | 0 | 0 | 0 | 0 | 1 | 0 | 0 | 0 | 0 | 0 | 0 | 0 | 0 | 0 | 0 |
| 8 | 0 | 0 | 0 | 0 | 0 | 0 | 0 | 0 | 1 | 0 | 0 | 0 | 0 | 0 | 0 | 0 | 0 | 0 |
| 9 | 0 | 0 | 0 | 0 | 0 | 0 | 0 | 0 | 0 | 1 | 0 | 0 | 0 | 0 | 0 | 0 | 0 | 0 |
| 10 | 0 | 0 | 0 | 0 | 0 | 0 | 0 | 0 | 0 | 0 | 1 | 0 | 0 | 0 | 0 | 0 | 0 | 0 |
| 11 | 0 | 0 | 0 | 0 | 0 | 0 | 0 | 0 | 0 | 0 | 0 | 1 | 0 | 0 | 0 | 0 | 0 | 0 |
| 12 | 0 | 0 | 0 | 0 | 0 | 0 | 0 | 0 | 0 | 0 | 0 | 0 | 1 | 0 | 0 | 0 | 0 | 0 |
| 13 | 0 | 0 | 0 | 0 | 0 | 0 | 0 | 0 | 0 | 0 | 0 | 0 | 0 | 1 | 0 | 0 | 0 | 0 |
| 14 | 0 | 0 | 0 | 0 | 0 | 0 | 0 | 0 | 0 | 0 | 0 | 0 | 0 | 0 | 1 | 0 | 0 | 0 |
| 15 | 0 | 0 | 0 | 0 | 0 | 0 | 0 | 0 | 0 | 0 | 0 | 0 | 0 | 0 | 0 | 1 | 0 | 0 |
| 16 | 0 | 0 | 0 | 0 | 0 | 0 | 0 | 0 | 0 | 0 | 0 | 0 | 0 | 0 | 0 | 0 | 1 | 0 |
| 17 | 0 | 0 | 0 | 0 | 0 | 0 | 0 | 0 | 0 | 0 | 0 | 0 | 0 | 0 | 0 | 0 | 0 | 1 |
| 18 | 1 | 0 | 0 | 0 | 0 | 1 | 0 | 1 | 0 | 0 | 1 | 0 | 0 | 0 | 0 | 0 | 0 | 0 |
| 19 | 0 | 1 | 0 | 0 | 0 | 0 | 1 | 0 | 1 | 0 | 0 | 1 | 0 | 0 | 0 | 0 | 0 | 0 |
| 20 | 0 | 0 | 1 | 0 | 0 | 0 | 0 | 1 | 0 | 1 | 0 | 0 | 1 | 0 | 0 | 0 | 0 | 0 |
| 21 | 0 | 0 | 0 | 1 | 0 | 0 | 0 | 0 | 1 | 0 | 1 | 0 | 0 | 1 | 0 | 0 | 0 | 0 |
| 22 | 0 | 0 | 0 | 0 | 1 | 0 | 0 | 0 | 0 | 1 | 0 | 1 | 0 | 0 | 1 | 0 | 0 | 0 |
| 23 | 0 | 0 | 0 | 0 | 0 | 1 | 0 | 0 | 0 | 0 | 1 | 0 | 1 | 0 | 0 | 1 | 0 | 0 |
| 24 | 0 | 0 | 0 | 0 | 0 | 0 | 1 | 0 | 0 | 0 | 0 | 1 | 0 | 1 | 0 | 0 | 1 | 0 |
| 25 | 0 | 0 | 0 | 0 | 0 | 0 | 0 | 1 | 0 | 0 | 0 | 0 | 1 | 0 | 1 | 0 | 0 | 1 |
| 26 | 1 | 0 | 0 | 0 | 0 | 1 | 0 | 1 | 1 | 0 | 1 | 0 | 0 | 1 | 0 | 1 | 0 | 0 |
| 27 | 0 | 1 | 0 | 0 | 0 | 0 | 1 | 0 | 1 | 1 | 0 | 1 | 0 | 0 | 1 | 0 | 1 | 0 |
| 28 | 0 | 0 | 1 | 0 | 0 | 0 | 0 | 1 | 0 | 1 | 1 | 0 | 1 | 0 | 0 | 1 | 0 | 1 |
| 29 | 1 | 0 | 0 | 1 | 0 | 1 | 0 | 1 | 1 | 0 | 0 | 1 | 0 | 1 | 0 | 0 | 1 | 0 |
| 30 | 0 | 1 | 0 | 0 | 1 | 0 | 1 | 0 | 1 | 1 | 0 | 0 | 1 | 0 | 1 | 0 | 0 | 1 |
| 31 | 1 | 0 | 1 | 0 | 0 | 0 | 0 | 0 | 0 | 1 | 0 | 0 | 0 | 1 | 0 | 1 | 0 | 0 |

Tables 1 and 2 show that the output values are the same. The right most or most significant bit of these tables are the same. Tables 1 and 2 also show that the first 8 bits of the Fibonacci sequence state and the last 8 bits of the Galois sequence state are identical though time reversed. The advantage of the Fibonacci generator is that all of the future bits from the current time up to the size of the shift register can be extracted from the current state. So inspection of the Fibonacci sequence shows that any state i contains the future N−1 output bits giving immediate access to the required N bits for a parallel update. This allows a single update from the Fibonacci generator to generate up to 18 bits for each output with no modification in this example.

For a maximal length LFSR both the Fibonacci and Galois forms of the generator generate the same output sequence, but shifted in time. This can be shown as follows. Let c_{F}^{(k)} be the sequence of bits generated by the Fibonacci form and c_{G}^{(k)} be the sequence generated by the Galois form. If we take the initial state for the Fibonacci form generator S_{F}⁽⁰⁾ to be [1,0,0 . . . 0]^{T}, then from FIG. 5 it is easy to see that:
c_{F}^{(k)}=[1,0,0 . . . 0]M^{(k)}[1,0,0 . . . 0]^{T} (9)
Similarly, for S_{G}⁽⁰⁾ to be [1,0,0 . . . 0]^{T}, then:
c_{G}^{(k)}=[1,0,0, . . . 1]M^{(k)}^{^{T}}[1,0,0 . . . 0] (10)
Noting that [0,0,0 . . . 0,1]=[1,0,0 . . . 0] M⁽¹⁾^{^{T}}, we have:
c_{G}^{(k)}=[1,0,0 . . . 0]M^{(k+1)}^{^{T}}[1,0,0 . . . 0]^{T} (11)
Equations (6) and (8) together imply that c_{G}^{(k)}=c_{F}^{(k+1)}. Thus, when S_{G}⁽⁰⁾=[1,0,0 . . . 0]^{T}=S_{F}⁽⁰⁾, the Galois generator generates the same sequence as the Fibonacci generator, except for a shift of one bit.

This can be generalized to arbitrary initial states. Suppose the Fibonacci and Galois form generators starts with respective arbitrary initial states S_{F}⁽⁰⁾ and S_{G}⁽⁰⁾. Since for a maximal length LFSR every non-zero state is reachable from every other state in a number of steps less than 2^{N}−1 steps, there exists α and β such that S_{F}⁽⁰⁾=M^{(α)}[1,0,0 . . . 0]^{T} and S_{G}⁽⁰⁾=M^{(β)}[1,0,0 . . . 0]^{T}. Therefore:

$$\begin{matrix}{c}_{F}^{( k )} = [ 1 , 0 , 0 … 0 ] {M}^{( k )} {S}_{F}^{( 0 )} \\ = [ 1 , 0 , 0 … 0 ] {M}^{( k )} {{M}^{( \cdot )} [ 1 , 0 , 0 … 0 ]}^{T} \\ = {S}^{{( 0 )}^{T}} {{M}^{( k + α - β - 1 )} [ 0 , 0 , 0 … 1 ]}^{T} \\ = {c}_{G}^{( k + α - β - 1 )}\end{matrix}$$

The Fibonacci and Galois form generators produce identical bitstreams, except for a constant shift of (k+α−β−1) modulo2^{(N-1)}.

The Fibonacci generator however must be built in the power matrix form to be able to generate sequences at arbitrary phases and update them by arbitrary amounts. In contrast, the Galois state contains some of the Fibonacci state bits but then is broken up into seemingly random groups of bits that are delayed versions of the required sequences.

In the Galois sequence the feedback taps form discontinuities in the sequences. The number of these discontinuities is equal to the number of tap weights. However the cost of a general purpose Fibonacci machines is high. If the Galois state can be mapped in a relatively simple way to give the same exact state output as the Fibonacci sequence then a general purpose parallel output scramble code generator can be built with low storage costs.

A general purpose Fibonacci generator requires over 4000 bytes of storage ((32*32*32)/8). In contrast, in theory a Galois programmed machine would require only 12 bytes of storage (32*3/8) assuming largest polynomial was 32. For multiple standard support this invention is most attractive. For single standard support this invention is still competitive especially on a software platform. The main reason for the large reduction in storage is due to the regular repetitive structure of the mappings.

The states of the 2 machines are represented in this application with the most significant bit or output bit on the right hand side. The time offsets of the sequences were measured by exhaustive search. In the Fibonacci sequence all of the time shifts are simple, incrementing by 1 each time.
α¹⁷,α¹⁶,α¹⁵,α¹⁴, α¹³,α¹²,α¹¹,α¹⁰,α⁹,α⁸,α⁷,α⁶,α⁵,α⁴,α³,α²,α¹,α⁰
   The columns of the Galois sequence however have the following time shifts:
α⁰,α¹,α²,α⁴,α⁵,α⁶,α⁷,α⁷⁹⁶⁰⁷,α⁷⁹⁶⁰⁸,α⁷⁹⁶⁰⁹,α¹⁰⁵²²,α¹⁰⁵²³,α⁻⁵,α⁻⁴,α⁻³,α⁻²,α⁻¹
   which are shown in reverse order. A linear mapping is thus possible given the additive shift property.

Generating these time shifts would seem like a complex problem. This application defines a model of the way the sequences for each state bit are related to each other referred to here as the recursive definition of the code. Each bit along the state is an earlier time sequence of the previous one. This is equivalent of saying the next sequence is α⁻¹ multiplied by of the current state. This is true until a feedback tap is encountered then the most significant bit, the earliest bit of the generator used as the feedback bit is added to the current state bit. This new state bit is then multiplied by α⁻¹ as before until it meets the next feedback bit and so on.

For a Fibonacci machine the following is true:

$$\begin{matrix}\begin{matrix}{s}_{i + 1} = {s}_{i} * {α}^{1} & For i 0 to n - 2\end{matrix} & ( 12 ) \\ \begin{matrix}{s}_{n - 1} = {\sum }_{i = 0}^{n - 1} {s}_{i} {g}_{i} {α}^{i} & Feed \text{-} forward equation\end{matrix} & ( 13 )\end{matrix}$$

The feed forward equation is the same as the polynomial definition of the code.

For a Galois machine there is the following relation between states. The feedback path is directly connected to the first bits of the sequence so the least significant bit of the state becomes the most significant bit of the state on each clock pulse. If a feedback tap occurs, the next state is the sum of the current state and the original output bit delayed by 1.
sᵢ₊₁=(sᵢ+gᵢ)α⁻¹ (14)
sₒ=sₙ₋₁α⁻¹ (15)
Consider the example of the downlink code G=X¹⁸+X¹⁰+X⁷+X⁵+1. According to these rules the sequence of ratios between each state bit and state bit zero (the output of the last state bit) is:
S17=(((α⁻⁵+α⁰)·α⁻¹³+α⁰)·α⁻³+α⁰)·α⁻⁸,(=α⁰)
S16=(((α⁻⁵+α⁰)·α⁻¹²+α⁰))·α⁻³+α⁰)·α⁻⁷,(=α¹)
S15=(((α⁻⁵+α⁰)·α⁻¹¹+α⁰))·α⁻³+α⁰)·α⁻⁶,(=α²)
S14=(((α⁻⁵+α⁰)·α⁻¹⁰+α⁰))·α⁻³+α⁰)·α⁻⁵,(=α³)
S13=(((α⁻⁵+α⁰)·α⁻⁹+α⁰))·α⁻³+α⁰)·α⁻⁴,(=α⁴)
S12=(((α⁻⁵+α⁰)·α⁻⁸+α⁰))·α⁻³+α⁰)·α⁻³,(=α⁵)
S11=(((α⁻⁵+α⁰)·α⁻⁷+α⁰))·α⁻³+α⁰)·α⁻²,(=α⁶)
S10=(((α⁻⁵+α⁰)·α⁻⁶+α⁰))·α⁻³+α⁰)·α⁻¹,(=α⁷)
S9=((α⁻⁵+α⁰)·α⁻⁵+α⁰)·α⁻³,
S8=α⁻⁵+α⁰)·α⁻⁴+α⁰)·α⁻²,
S7=α⁻⁵+α⁰)·α⁻³+α⁰)·α⁻¹,
S6=(α⁻⁵+α⁰)·α⁻²,
S5=(α⁻⁵+α⁰)·α⁻¹,
S4=α⁻⁵,
S3=α⁻⁴,
S2=α⁻³,
S1=α⁻²,
S0=α⁻¹
This shows the state is not a continuous sequence of values, there are discontinuities due to bits 0 to 9 not following the sequence of the other entries. The sequence needs to be of the form of the Fibonacci machine. By inspection it is shown that:
(((α⁻⁵+α⁰)α⁻⁶+α⁰)α⁻³+α⁰)α⁻¹=α⁷ (13)
Which is equivalent to:
α⁻¹¹+α⁻⁶+α⁻⁴+α⁻¹=α⁷ (17)
Multiplying both sides by α¹¹ returns the generator polynomial where f(α)=0:
α¹⁸+α¹⁰+α⁷+⁵+α⁰=0 (18)
Thus many of the required bits are in the form needed but some have to be reconstructed. The missing parts are all available or can be generated. This process can be performed by hand for any code but it is laborious. This process is detailed below. The equations are expanded out to form normal polynomial equations. It is now clear which missing values are needed to reconstruct the equivalent Fibonacci state. By inspection it is seen that if state0 is α⁻¹ then state17 must be α⁰ as they are directly connected and so on until the first feedback tap is encountered. Thus the missing values to make the state the same as the Fibonacci state are all available but reversed from least significant bit to most significant bit. Thus there is a mapping from the Galois state to the Fibonacci state. There may still be an arbitrary time offset between the 2 state spaces.
α⁻¹⁸+α⁻¹³+α⁻¹¹+α⁻⁸,(=α⁰)
α⁻¹⁷+α⁻¹²+α⁻¹⁰+α⁻⁷,(=α¹)
α⁻¹⁶+α⁻¹¹+α⁻⁹+α⁻⁶,(=α²)
α⁻¹⁵+α⁻¹⁰+α⁻⁸+α⁻⁵,(=α³)
α⁻¹⁴+α⁻⁹+α⁻⁷+α⁻⁴,(=α⁴)
α⁻¹³+α⁻⁸+α⁻⁶+α⁻³,(=α⁵)
α⁻¹²+α⁻⁷+α⁻⁵+α⁻²,(=α⁶)
α⁻¹¹+α⁻⁶+α⁻⁴+α⁻¹,(=α⁷)
α⁻¹⁰+α⁻⁵+α⁻³(+α⁰),(=α⁸)
α⁻⁹+α⁻⁴+α⁻²(+α¹),(=α⁹)
α⁻⁸+α⁻³+α⁻¹(+α²),(=α¹⁰)
α⁻⁷+α⁻²(+α⁰+α³),(=α¹¹)
α⁻⁶+α⁻¹(+α¹+α⁴),(=α¹²)
α⁻⁵(+α⁰+α²+α⁵),(=α¹³)
α⁻⁴(+α¹+α³+α⁶),(=α¹⁴)
α⁻³(+α²+α⁴+α⁷),(=α¹⁵)
α⁻²(+α³+α⁵+α⁸),(=α¹⁶)
α⁻¹(+α⁴+α⁶+α⁹),(=α¹⁷)
The above sequence is combined with itself in the above manner to generate a contiguous sequence. The missing part of the sequence is shown in parentheses. Contiguity is defined by the next bit being a delayed version of the previous bit. Each element in the state is a delayed version of the previous state the same as a Fibonacci sequence. Feed forward matrix F shown below is used to convert the Galois field state into the Fibonacci sequence. This matrix has a special structure. Every column is an up shifted copy of the previous column. This matrix F is added to the identity to form the full feed forward matrix. Only N bits are required to define the functionality of the converter. This allows the structure of the feed forward unit to be highly regular and optimized. It only requires N control inputs.

This is a recursive method that defines the time relationship between each bit in the Galois state. Upon calculation of the coefficient between state bit I and state bit 0, the antilog in the polynomial field of interest yields the actual time offset. For example with bit 9:
α⁻¹⁰+α⁻⁵+α⁻³=α⁷⁹⁶⁰⁷ (19)
From equation (19), we have:
offset(9)=antilog(α⁻¹⁰+α⁻⁵+α⁻³)=79607 (20)
The recursive definition for each code can be used to form a lookup table that allows the mask value used in the example CDMA2000 in the long code to be converted to a multiplicative coefficient to allow the Galois machine to still be used for parallel sequence extraction. The required extra bits added are shown below. Each vertical column i−1 is a shifted version of column i:

$$F = [ \begin{matrix}1 & 0 & 0 & 0 & 0 & 0 & 0 & 0 & 1 & 0 & 0 & 1 & 0 & 1 & 0 & 0 & 1 & 0 \\ 0 & 1 & 0 & 0 & 0 & 0 & 0 & 0 & 0 & 1 & 0 & 0 & 1 & 0 & 1 & 0 & 0 & 1 \\ 0 & 0 & 1 & 0 & 0 & 0 & 0 & 0 & 0 & 0 & 1 & 0 & 0 & 1 & 0 & 1 & 0 & 0 \\ 0 & 0 & 0 & 1 & 0 & 0 & 0 & 0 & 0 & 0 & 0 & 1 & 0 & 0 & 1 & 0 & 1 & 0 \\ 0 & 0 & 0 & 0 & 1 & 0 & 0 & 0 & 0 & 0 & 0 & 0 & 1 & 0 & 0 & 1 & 0 & 1 \\ 0 & 0 & 0 & 0 & 0 & 1 & 0 & 0 & 0 & 0 & 0 & 0 & 0 & 1 & 0 & 0 & 1 & 0 \\ 0 & 0 & 0 & 0 & 0 & 0 & 1 & 0 & 0 & 0 & 0 & 0 & 0 & 0 & 1 & 0 & 0 & 1 \\ 0 & 0 & 0 & 0 & 0 & 0 & 0 & 1 & 0 & 0 & 0 & 0 & 0 & 0 & 0 & 1 & 0 & 0 \\ 0 & 0 & 0 & 0 & 0 & 0 & 0 & 0 & 1 & 0 & 0 & 0 & 0 & 0 & 0 & 0 & 1 & 0 \\ 0 & 0 & 0 & 0 & 0 & 0 & 0 & 0 & 0 & 1 & 0 & 0 & 0 & 0 & 0 & 0 & 0 & 1 \\ 0 & 0 & 0 & 0 & 0 & 0 & 0 & 0 & 0 & 0 & 1 & 0 & 0 & 0 & 0 & 0 & 0 & 0 \\ 0 & 0 & 0 & 0 & 0 & 0 & 0 & 0 & 0 & 0 & 0 & 1 & 0 & 0 & 0 & 0 & 0 & 0 \\ 0 & 0 & 0 & 0 & 0 & 0 & 0 & 0 & 0 & 0 & 0 & 0 & 1 & 0 & 0 & 0 & 0 & 0 \\ 0 & 0 & 0 & 0 & 0 & 0 & 0 & 0 & 0 & 0 & 0 & 0 & 0 & 1 & 0 & 0 & 0 & 0 \\ 0 & 0 & 0 & 0 & 0 & 0 & 0 & 0 & 0 & 0 & 0 & 0 & 0 & 0 & 1 & 0 & 0 & 0 \\ 0 & 0 & 0 & 0 & 0 & 0 & 0 & 0 & 0 & 0 & 0 & 0 & 0 & 0 & 0 & 1 & 0 & 0 \\ 0 & 0 & 0 & 0 & 0 & 0 & 0 & 0 & 0 & 0 & 0 & 0 & 0 & 0 & 0 & 0 & 1 & 0 \\ 0 & 0 & 0 & 0 & 0 & 0 & 0 & 0 & 0 & 0 & 0 & 0 & 0 & 0 & 0 & 0 & 0 & 1\end{matrix} ]$$

In the case of the existing Galois state, for any particular code the table of coefficients which advance the state to the required point can be generated. The vector of inputs α⁻¹, α⁻², α^{-N+1}, α^{-N} is multiplied by the tap weight vector matrix TWM. The TWM has the structure shown in below. The feedback taps are promoted from GF(2) to GF(2^{N}):

$$[ \begin{matrix}{M}_{N - 1} \\ {M}_{N - 2} \\ {M}_{N - 3} \\ ⋯ \\ ⋯ \\ {M}_{2} \\ {M}_{1} \\ {M}_{0}\end{matrix} ] = [ \begin{matrix}{g}_{N - 1} & {g}_{N - 2} & {g}_{N - 3} & ⋯ & ⋯ & {g}_{2} & {g}_{1} & 1 \\ {g}_{N - 2} & {g}_{N - 3} & {g}_{N - 4} & ⋯ & ⋯ & {g}_{1} & 1 & 0 \\ {g}_{N - 3} & {g}_{N - 4} & {g}_{N - 5} & ⋯ & ⋯ & 1 & 0 & 0 \\ ⋯ & ⋯ & ⋯ & ⋯ & ⋯ & 0 & 0 & 0 \\ {g}_{3} & {g}_{2} & {g}_{1} & 1 & ⋯ & 0 & 0 & 0 \\ {g}_{2} & {g}_{1} & 1 & 0 & ⋯ & 0 & 0 & 0 \\ {g}_{1} & 1 & 0 & 0 & ⋯ & 0 & 0 & 0 \\ 1 & 0 & 0 & 0 & ⋯ & 0 & 0 & 0\end{matrix} ] \cdot [ \begin{matrix}{α}^{- 1} \\ {α}^{- 2} \\ {α}^{- 3} \\ ⋯ \\ ⋯ \\ {α}^{- N + 2} \\ {α}^{- N + 1} \\ {α}^{- N}\end{matrix} ] \qquad ( 21 )$$

For the polynomial

$$g ( X ) = {\sum }_{i = 0}^{N - 1} {g}_{i} {X}^{i}$$

where: X=α and g(α)=0 is a primitive element of the field. This means in the example shown that α⁻¹⁸+α⁻¹³+α⁻¹¹+α⁻⁸=α⁰ since α¹⁸+α¹⁰+α⁷+α⁵+α⁰=0. In other words M^{N-1}=α⁰=1.

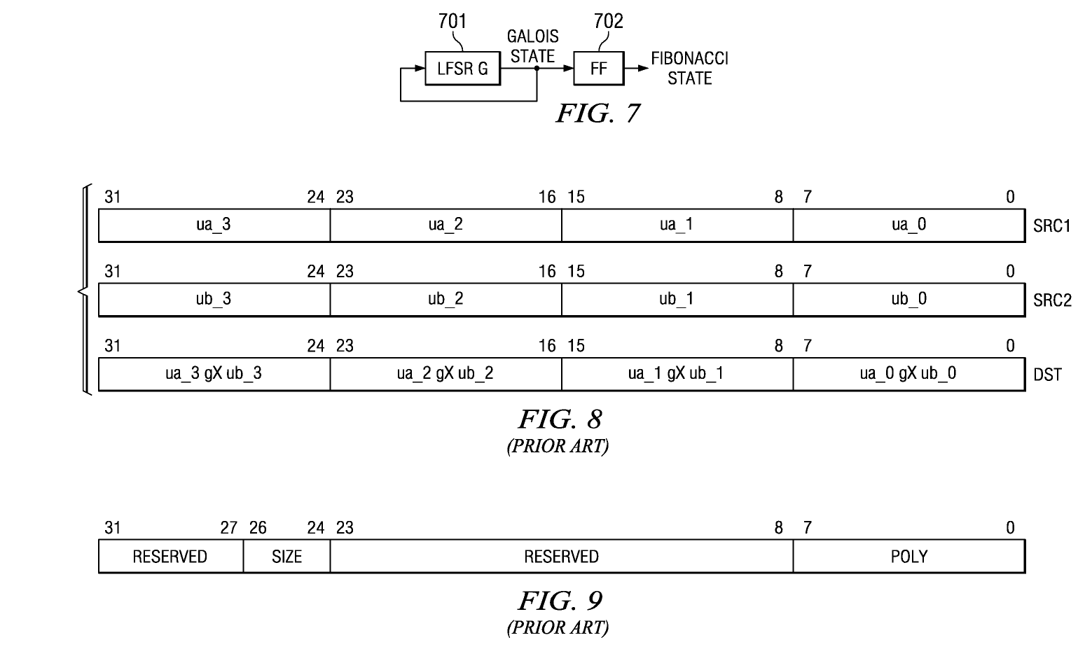

FIG. 7 illustrates an example use of this invention. This example includes a Galois field generator 701 followed by a feed forward converter 702 generating the corresponding Fibonacci state as illustrated in FIG. 5. The Galois field generator 701 requires the correct initial state to form an equivalent generator to a Fibonacci machine. There is a matrix FF which can convert Fibonacci state space to Galois field state space. Thus the inverse FF matrix should map the known Fibonacci state to the required Galois state. This permits generating the Galois state from this point and then converting back to the Fibonacci state using FF.
S_{G0}=FF⁻¹S_{F0} (22)
The initial Galois state is determined from the desired initial Fibonacci state using inverse mapping.
S_{Gi}=GⁱS_{G0} [symbol] α¹ [symbol] S_{G0} (23)
This method then arbitrarily advances from time zero to time to form Galois state at time i. Note the equivalence:
S_{Fi}=FFS_{Gi} (24)
Equation (24) forward maps from Galois state to Fibonacci state and accesses to parallel output bits.

The following algorithm is a closed form deterministic method of calculating the feed-forward matrix. The polynomial matrix is defined as:

$$G = [ \begin{matrix}0 & 1 \\ I & {g}^{T}\end{matrix} ] \qquad ( 25 )$$

The 0th column of the matrix G is the Generator polynomial g multiplied by the up shift matrix R where:

$$R = [ \begin{matrix}0 & I \\ 0 & 0\end{matrix} ] \qquad ( 26 )$$

The matrix G can also be considered as the Galois generator matrix down shifted by 1 and the 0^{th} element set to 1.

It is known that any bit sequence from the Fibonacci sequence is equal to the equivalent Galois sequence with an arbitrary shift. The contiguous sequence of outputs for a particular state can also be produced using the following equivalence. For a particular state α^{k} there is an output bit Xₖ. The output bit Xₖ₊₁ is generated form the same bit position from state α^{k+I}. This is repeated up to N bits in the state. To merge the output bits the matrix R is upshifted. The total combination of bits from state k can then be expressed as the matrix F where G is the Galois field generator matrix:

$$F = {\sum }_{i = 0}^{N - 1} {R}^{i} {e}_{0} {e}_{0}^{T} {G}^{i} , \\ {e}_{0} = {[ 0 , 0 , 0 , 0 , 0 , … , 1 ]}^{T} , \\ {G}^{0} = I , \\ {R}^{0} = I \qquad ( 27 )$$

The matrix F performs a store of the N outputs form the most significant bit of the Galois state. The Galois field multiplier advances the state by a block of time samples. The resulting matrix always has full rank N. All elements on the diagonal are 1 and the matrix is always upper triangular and per-symmetric. Therefore this matrix cannot have zero determinant and is thus always invertible. The rows are last row of every power of G from 0 to N−1.

This provides a mapping from a particular g-space state to the equivalent f-space state. To produce the g-space state for a particular f-space state requires the inverse of F. It is straightforward to calculate the inverse in an iterative manner by a technique called inverse iteration. The feed forward matrix FF to convert a Fibonacci state to a Galois state is its self inverse in many polynomials. In the case of the downlink 3GPP scramble code generators and 1 downlink generator this is true.

The matrix F has a known formula, but none is known for its inverse. The inverse iteration selects the initial estimate of F⁻¹ to be F. The product of these two matrices is added to the identity matrix to form an error matrix e. This is added GF(2) to the estimate of E-1. This is repeated up to N times and always generates the inverse. The algorithm always yields the inverse because the feed forward matrix and the inverse are per-symmetric and lower triangular so that only one bit needs to be changed to correct the whole diagonal at each stage. Once the bit has been set to the correct value all subsequent iterations are orthogonal. This algorithm is summarized as follows:
F₀⁻¹=F:i=0
E=F⁻¹ᵢ·F+I
if |E|=0:stop
F⁻¹ᵢ₊₁=F⁻¹ᵢ+E:i=1, . . . ,N−1
Often the iteration meet the stop condition while requiring fewer than N−1 iterations. In the case of the 42-bit IS95 long code only 4 iterations are needed. The 18-bit 3GPP downlink Y scramble code needs only 1 iteration. The matrices are generally sparse and so only a few non zero diagonals need to be corrected.

A mapping is always needed from the Fibonacci form to the Galois form any time the initial state is arbitrary, thus it is necessary to know the inverse. Thus to preserve the initial state it must first be mapped from Fibonacci to Galois to that it can then be transformed back to Fibonacci.

It is now possible to show the actual time difference between the 2 sequences. The initial state for the Galois machine is chosen as a known value SG₀ and the output is taken from bit N−1. The feed-forward matrix F is then applied to this state to produce the equivalent Fibonacci field element. The output from bit 0 is used as the sequence and will be identical to the Fibonacci sequence. A unique feed-forward F can be calculated for a specific polynomial. This gives the required initial starting state of the Fibonacci generator to make the 2 sequences the same.
SF₀=F·SG₀ (28)
By having the same state SF₀ in both machines the output sequences will be offset in phase. We are in a position to calculation this phase for a particular initial Fibonacci state.
SG₀=α^{g}SF₀=F·α^{g}
SF₀=α^{f} [symbol] α^{f}=F·α^{g} [symbol]
f=anti log_{α}(F·α^{g}) [symbol]
offset=anti log_{α}(F·α^{g})−g
Thus the difference between the two sequences is related, but depends on the actual initial state. If we choose g=0, then we can simplify this equation. With g=0, SF₀ is 1 in the most significant bit and zero elsewhere. Multiplying this by F will produce the same value. As predicted in the proof offset=0.

$$[ \begin{matrix}1 & {f}_{n - 2} & {f}_{n - 3} & ⋮ & {f}_{1} & {f}_{0} \\ 0 & 1 & {f}_{n - 2} & {f}_{n - 3} & ⋮ & {f}_{1} \\ 0 & 0 & 1 & {f}_{n - 2} & {f}_{n - 3} & ⋮ \\ ⋮ & 0 & 0 & 1 & {f}_{n - 2} & {f}_{n - 3} \\ 0 & ⋮ & 0 & 0 & 1 & {f}_{n - 2} \\ 0 & 0 & ⋮ & 0 & 0 & 1\end{matrix} ] \cdot [ \begin{matrix}1 \\ 0 \\ 0 \\ ⋮ \\ 0 \\ 0\end{matrix} ] = [ \begin{matrix}1 \\ 0 \\ 0 \\ ⋮ \\ 0 \\ 0\end{matrix} ] \qquad ( 29 )$$

for an arbitrary state, the offset is an unpredictable combination of elements in feed forward matrix. The following is an example implementing a generator using these methods.

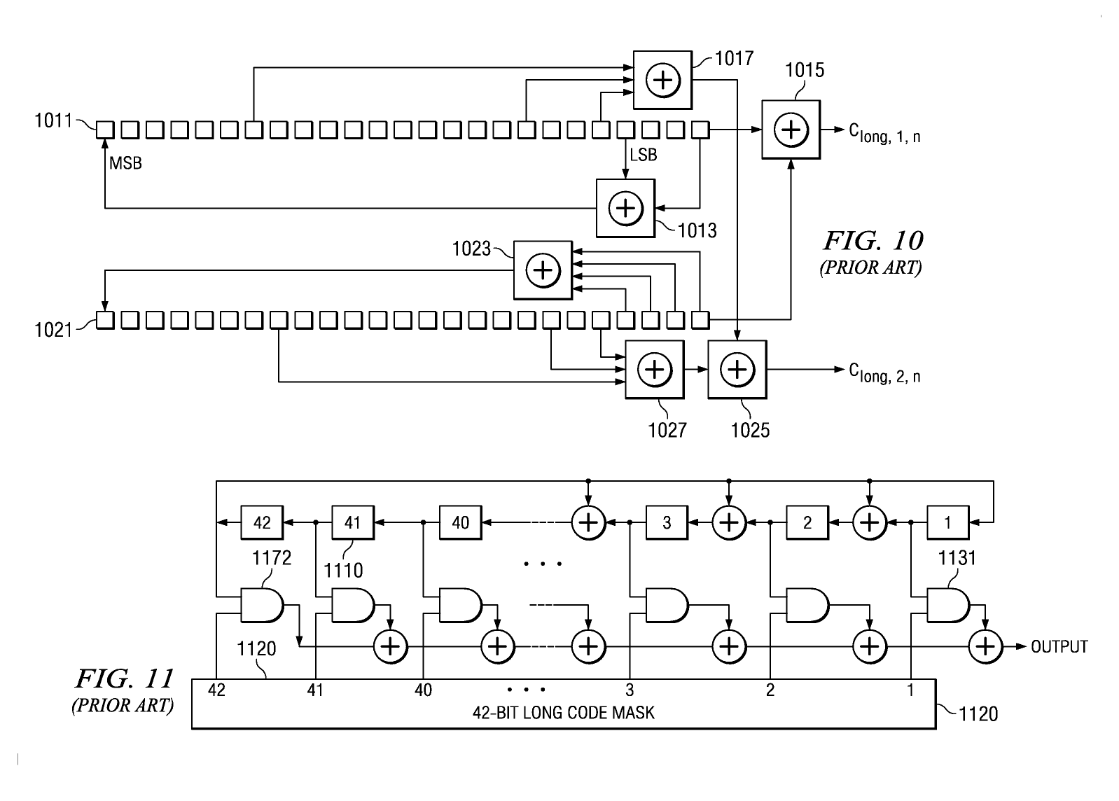

The following example is a design of an equivalent Galois generator structure for the 3GPP uplink scramble code. This is a combination of 2 Fibonacci generators X and Y. FIG. 10 illustrates the linear feedback shift register form of the scramble code generator. FIG. 10 illustrates generator X shift register 1011 and generator Y shift register 1021.

Generator polynomial X is g(X)=X²⁵+X³+1 provided by summer 1013. Generator polynomial Y is f(X)=X²⁵+X³+X²+X+1 provided by summer 1023. The initial state of X is a 24 bit number with the twenty fifth state bit set to 1, thus the initial state is n0, n1, n2, n3, n4, n5, n6, n7, n8, n9, n10, n11, n12, n13, n14, n15, n16, n17, n18, n19, n20, n21, n22, n23, ‘1.’ The initial state of Y is all ones. The 2 generators are then summed together modulo 2 in summer 1015. This forms the in-phase part of the sequence. The quadrature part is the same sequence delayed by 16,777,232 chips. The delay is formed in summers 1017 and 1027. Summer 1025 modulo 2 sums these delayed signals for the quadrature output.

The generator matrix for the Fibonacci form is:

$${G}_{F} = [ \begin{matrix}0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 1 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 1 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 1 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 1 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 1 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 1 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 1 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 1 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 1 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 1 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 1 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 1 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 0 & 1 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 0 & 0 & 1 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 1 & 0 \\ 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 1 \\ 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0\end{matrix} ]$$

$${α}^{24} , {α}^{23} , {α}^{22} , {α}^{21} , {α}^{20} , {α}^{19} , {α}^{18} , {α}^{17} , {α}^{16} , {α}^{15} , {α}^{14} , {α}^{13} , {α}^{12} , {α}^{11} , {α}^{10} , {α}^{9} , {α}^{8} , {α}^{7} , {α}^{6} , {α}^{5} , {α}^{4} , {α}^{3} , {α}^{2} , {α}^{1} , {α}^{0}$$

Code X has feed forward taps at α⁴, α⁷ and α¹⁸. These are added together to form the delay. The Galois generator is shown below.

$${G}_{G} = [ \begin{matrix}0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 1 \\ 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 1 \\ 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 1 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 1 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 1 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 1 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 1 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 1 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 1 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 1 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 1 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 1 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 1 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 1 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 0 & 1 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 0 & 0 & 1 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 1 & 0\end{matrix} ]$$

The next step is to calculate the feed forward matrix to convert G to F using the algorithm disclosed above. The feed forward matrix is a self inverse for both codes. Applying the algorithm gives the following feed forward matrix:

$$FF = [ \begin{matrix}1 & 0 & 0 & 0 & 0 & 0 & 0 & 0 & 0 & 0 & 0 & 0 & 0 & 0 & 0 & 0 & 0 & 0 & 0 & 0 & 0 & 0 & 1 & 0 & 0 \\ 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 1 & 0 \\ 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 1 \\ 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 1 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 1 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 1 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 1 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 1 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 1 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 1 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 1 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 1 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 1 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 1 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 1 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 0 & 1 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 0 & 0 & 1 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 1 & 0 \\ 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 1\end{matrix} ]$$

This matrix has the same effect as adding (modulo 2) the state to shifted versions of itself. Each diagonal in the feed forward (or feedback) matrix is equivalent to a shift in value to the number of rows for the leading diagonal. So the identity is a shift of 0, in equation (30) the diagonal is 22 from the leading diagonal so is a right shift of 22. In this case:
StateX=StateXˆ(StateX>>22) (30)
In the case of generator X the initial state is defined as n₂₃ . . . n₀, the 24 bit binary representation of the scrambling sequence number n with n₀ being the least significant bit. The X sequence depends on the chosen scrambling sequence number n and is denoted xₙ. The initial conditions are: xₙ(24)=n₀, xₙ(23)=n₁, . . . xₙ(2)=n₂₂, xₙ(1)=n₂₃, xₙ(0)=1. This initial Fibonacci state must first be bit reversed because the state in the Fibonacci generator is defined to be a time reversed version of the Galois generator. This state is: bit reverse (0x1000000ⁿ). This value goes through the transformation in equation (30). In Galois field over the polynomial g(X)=X²⁵+X³+1, the feed forward path α⁴+α⁷+α¹⁸, is equal to the Galois field element 0x0040090. When the logarithm of this value is taken to the base of alpha the index is 16777232 as defined in the 3GPP standard. The delay coefficient will then form the initial value of the delayed version of the code. Generator X is thus completely defined using Galois field arithmetic.

The generator matrix for the Fibonacci form is:

$${G}_{F} = [ \begin{matrix}0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 1 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 1 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 1 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 1 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 1 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 1 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 1 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 1 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 1 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 1 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 1 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 1 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 0 & 1 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 0 & 0 & 1 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 1 & 0 \\ 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 1 \\ 1 & 1 & 1 & 1 & 0 & 0 & 0 & 0 & 0 & 0 & 0 & 0 & 0 & 0 & 0 & 0 & 0 & 0 & 0 & 0 & 0 & 0 & 0 & 0 & 0\end{matrix} ]$$

Code Y has feed forward taps at α⁴+α⁶+α¹⁷. These are added together to form the delay element. The Galois generator is:

$${G}_{G} = [ \begin{matrix}0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 1 \\ 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 1 \\ 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 1 \\ 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 1 \\ 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 1 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 1 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 1 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 1 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 1 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 1 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 1 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 1 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 1 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 1 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 1 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 1 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 0 & 1 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 1 & 0\end{matrix} ]$$

The process then calculates the feed forward matrix to convert from Galois form to Fibonacci form using the algorithm described above. Applying the algorithm produces the following feed forward matrix:

$$FF = [ \begin{matrix}1 & 0 & 0 & 0 & 0 & 0 & 0 & 0 & 0 & 0 & 0 & 0 & 0 & 0 & 0 & 0 & 0 & 0 & 0 & 0 & 0 & 0 & 1 & 1 & 1 \\ 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 1 & 1 \\ 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 1 \\ 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 1 & 0 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 1 & 0 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 1 & 0 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 1 & 0 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 1 & 0 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 1 & 0 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 1 & 0 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 1 & 0 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 1 & 0 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 1 & 0 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 1 & 0 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 1 & 0 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 0 & 1 & 0 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 0 & 0 & 1 & 0 & 0 \\ 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 1 & 0 \\ 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 1\end{matrix} ]$$

This matrix has the same effect as adding (modulo 2) the state to shifted versions of itself as shown in equation (31):
StateY=StateYˆ(StateY>>22)ˆ(StateY>>23)ˆ(StateY>>24) (31)
In the case of generator Y the initial Fibonacci state of 0x1FFFFFF is bit reversed and passed through the feedback matrix FF to form the constant initial value 0x1FFFFF8 in Galois the field, over the polynomial f(X)=X²⁵+X³+X²+X¹+1. The delayed sequence given by α⁴+α⁶+α¹⁷ is equal to the Galois filed element 0x020050. When the logarithm of this value is taken to the base of alpha the index is also 16777232 as defined in the 3GPP standard. This completely defines generator Y using Galois field arithmetic.

This method is summarized as follows. The Galois definition of scramble codes X is:
so=bitreverse(0x1000000ˆn)
XAᵢ=αⁱX₀::X₀=so [symbol] (so>>22)::f(x)=X²⁵+X³+1
F(XAᵢ)=XAᵢ [symbol] ⊕(XAᵢ>>22)
XBᵢ=αⁱX₀::X₀=(so⊕(so>>22)) [symbol] 0x040090
F(XBᵢ)=XBᵢ⊕(XBᵢ>>22)
The 2 sequences XA and XB are given the initial state. In the case of the delayed sequence the initial state is multiplied by the delay coefficient 0x040090. This is possible by the associative property of the multiplication. In these equations: the symbol ⊕ means the element wise modulo 2 addition in GF(2^{N}); and the symbol [symbol] means the multiplication in the Field GF(2^{N}). The Galois definition of scramble codes Y is:
so=bitreverse(0x1FFFFFF)
YAᵢ=αⁱY₀:Y₀=so⊕(so>>22)⊕(so>>23)⊕(so>>24)
f(X)=X²⁵+X³+X²+X¹+1
F(YAᵢ)=YAᵢ⊕(YAᵢ>>22)⊕(YAᵢ>>23)⊕(YAᵢ>>24)
YBᵢ=αⁱ [symbol] Y₀ [symbol] D₀:D₀=0x020050
F(YBᵢ)=YBᵢ⊕(YBᵢ>>22)⊕(YBᵢ>>23)⊕(YBᵢ>>24)
The nomenclature F(j) denotes the Fibonacci mapping using the feed forward matrix for each code. The scramble code state can be advanced by an arbitrary amount. Each output i contains 25 consecutive symbols:
YAᵢ=α^{k·i}·Y₀ (32)
The distance k between each block of symbols can be chosen by multiplying the state by α^{k} at each time instant i. It may be useful if the hardware is available to advance the sequence by a convenient amount such as 8, 16 or 24 symbols allowing more flexibility.

FIG. 11 illustrates an embodiment using a mask register. A new sequence is generated by exclusive ORing an arbitrary mask with the state. As an example, for the case CDMA2000 standard a 42-bit Galois LFSR 1110 is used this is masked with a 42-bit value stored in register 1120 via exclusive OR gates 1131 to 1172. The resulting bits summed together modulo 2 to produce a modified output. The bits in the state sequence are not contiguous as it is a Galois definition so the feed forward mapping is still required to convert to Fibonacci space. An arbitrary summation of different delayed versions of the sequence can produce the same sequence but delayed by another value. Using the recursive definition of the Galois field state and combinations of the mask bits to select which sequence offsets are summed together, a Galois field element can be constructed to cause the appropriate delay of the state sequence. The initial state is a given and the equivalent set of parallel outputs in Fibonacci space can be calculated using the feed forward matrix F. This allows the associativity of the multiplication process to be maintained. After applying the feed forward matrix the state can be advanced by an arbitrary amount and parallel blocks of bits read off.

Consider the example of the 3GPP downlink code G=X¹⁸+X¹⁰+X⁷+X⁵+1 to illustrate the different components of the Galois state. The following is called the recursive definition set and this is generated using the recursive definition method and the mapping describe above.
Tap17=α⁰=0x00001
Tap16=α¹=0x00002
Tap15=α²=0x00004
Tap14=α³=0x00008
Tap13=α⁴=0x00010
Tap12=α⁵=0x00020
Tap11=α⁶=0x00040
Tap10=α⁷=0x00080
Tap9=α⁻¹⁰+α⁻⁵+α⁻³=0x00101
Tap8=α⁻⁹+α⁻⁴+α⁻²=0x00202
Tap7=α⁻⁸+α^{-3+α}⁻¹=0x00404
Tap6=α⁻⁷+α⁻²=0x00809
Tap5=α⁻⁶+α⁻¹=0x01012
Tap4=α⁻⁵=0x02025
Tap3=α⁻⁴=0x0404a
Tap2=⁻³=0x08094
Tap1=α⁻²=0x0128
Tap0=α⁻¹=0x20250
If mask bits 2 and 4 were set the starting seed would be 0x08094ˆ0x02025=0x0a0b1. This would be post multiplied by a Galois field element to correct the sequence for the right current mask. This keeps the same hardware structure. The feed forward matrix is placed at the end of this chain. The initial seed is this element multiplied by the current initial seed.

In the case of the IS95 long code 42-bit code the table would contain 42 entries. For a software implementation these can be rapidly summed (modulo2) together, for a general speedup these can be encoded into groups of bits. In pairs of bits there would be 4 possible combinations of the 2 entries, making the table 4*42 entries. In groups of 3, 8*42 entries. A direct tradeoff of speed and memory can be made.

In a similar fashion to the section of a mask generation, an arbitrary time offset is often applied to the state to get the needed path delay and system time. Once this time is known, the code can be generated at the arbitrary instant in block format. C₀ is the offset coefficient.
C₀=α^{T}^{_{eff}} (33)
Assuming the time offset T is an N bit number, the time can be split into a product series as follows:

$${C}_{0} = {\prod }_{i = 0}^{N - 1} {α}^{{2}^{i} \cdot {T}_{i}} , \\ {T}_{off} = {\sum }_{i = 0}^{N - 1} {T}_{i} {2}^{i} , \\ {T}_{i} = \{ 0 , 1 \} \qquad ( 34 )$$

This results in a requirement to perform N−1 products. For the case of code X in the 3GPP uplink standard, the power series is shown in Table 3.

TABLE 3

| Bit position, i | Time offset 2ⁱ | Coefficient i, α²ⁱ |
|---|---|---|
| 0 | 1 | 0x00000002 |
| 1 | 2 | 0x00000004 |
| 2 | 4 | 0x00000010 |
| 3 | 8 | 0x00000100 |
| 4 | 16 | 0x00010000 |
| 5 | 32 | 0x00000780 |
| 6 | 64 | 0x00154000 |
| 7 | 128 | 0x0007fff8 |
| 8 | 256 | 0x01553546 |
| 9 | 512 | 0x00eeef9B |
| 10 | 1024 | 0x01d2c6c3 |
| 11 | 2048 | 0x000bcf8c |
| 12 | 4096 | 0x0054b848 |
| 13 | 8192 | 0x013fe9be |
| 14 | 16384 | 0x01d94543 |
| 15 | 32768 | 0x000f77ec |
| 16 | 65536 | 0x0114d5b6 |
| 17 | 131072 | 0x0096bc9d |
| 18 | 262144 | 0x00b7a6af |
| 19 | 524288 | 0x01eda42b |
| 20 | 1048576 | 0x00179a2a |
| 21 | 2097152 | 0x0143e424 |
| 22 | 4194304 | 0x01e81c07 |
| 23 | 8388608 | 0x0157e004 |
| 24 | 16777216 | 0x01ffe007 |

This table can predict a state 33 million chips ahead. This is equivalent of a path delay of abut 8.74 seconds, which is a million miles. A path delay of 100 Km is much as is probably required which is 2048 chips at 3.84 MHz. So 11 bits is enough.

The T_{off} value bits are scanned and the appropriate number of multiples are performed. This may be as many as 25. This is a time consuming process and would cause an increase in hardware to compute the coefficient. Therefore one solution is to group the bits into symbols, which are pre-computed products of elements in the table based on the active bits in the symbol. This is shown in equation (35):

$${C}_{0} = {\prod }_{i = 0}^{( N / M ) - 1} {\prod }_{j = 0}^{M - 1} {α}^{{2}^{M \cdot i}} \cdot {α}^{{2}^{j} \cdot {T}_{j + M \cdot i}} \qquad ( 35 )$$

Each block of M bits selects an entry in a table sized 2^{M}. Entries in this table are scaled by α²^{^{M1}}, where i is symbol number. For M=3 the table will have 8*24+1=193 entries. Taking every 3 bits of the time value, the calculation can be performed at three times the rate at the expense of 8 times the storage, which is the correct tradeoff for a software based solution. However with a requirement to limit the number of possible time bits a different trade off can be found. The method lends itself to redundant encoding to arbitrarily reduce the amount of Galois hardware versus additional configuration and storage.

The Texas Instruments TMS320C6400 class digital signal processor core such as described above in conjunction with FIGS. 1 to 4 has an extended Galois field multiplier instruction GMPY4. FIG. 8 illustrates the operation of the GMPY4 instruction. The GMPY4 instruction treats each source register src1 and src2 as four 8-bit data items packed into respective 32-data words. The GMPY4 instruction forms four Galois field products into respective bytes in the 32-bit resultant data word which is stored in the destination register. The GMPY4 instruction uses definitions stored in a Galois field polynomial generation function register illustrated in FIG. 9, which is a control register located in control registers 13 (FIG. 2). Bits 24 to 26 of this control register store data indicating the size of the Galois field arithmetic. Bits 0 to 7 store data indicating the polynomial generator. Either M unit 24 or 34 executes the GMPY4 instruction. This is known as a multi-cycle instruction with the resultant written into the corresponding register file during the Execute 4 pipeline phase 334. Other hardware is feasible to perform other Galois field multiplications. A particularly useful Galois field multiplication is a 9 bit by 32 bit multiplication. A full 32 by 32 multiplications can be achieved using such an instruction using the following identity:
A·B=A0·B+A1·B·α⁸·α⁸+A3·B·α⁸·α⁸·α⁸ (36)
Where A0, A1, A2 and A3 are the first, second, third and fourth byte respectively in a 32-bit data word A. This method can be used to generate the arbitrary time offset calculations and calculation of the initial state values for the 4 generators. A full 32 by 32 multiplication can be using the illustrated GMPY4 instruction with similar production of partial products and addition.

Scramble code generator is split into 2 parts. The first part generates the required states for a particular time offset. This can be performed every frame or even every call and then tracked. Thus the processing overhead can be highly amortized. The second part generates blocks of the scramble code in as efficient manner as possible. In appendices section list the c code that generates the 4 required initial states for scramble code generation. This function takes 129 cycles to execute. It only has to be called once per frame. Once the initial conditions have been generated the codes can be generated in bulk. The most convenient block of generation is 8 bits of each polynomial per iteration. The four 8-bit quantities are combined to form eight 2-bit scramble codes. The equations C_{long,1,n}(i)=XA(i)+YA(i) and C_{long,2,n}(i)=XB(i)+YB(i) form the in phase and quadrature sequences. These are then further combined using the following equation:
C_{long,n}(i)=c_{long,l,n}(i)(1+j(−1)ⁱc_{long,2,n}(2└i/2┘)) (37)

In the following sequence 8 bits of code1 are represented as C1 and 8 bits of code are represented as C2 is represented the in phase 8 bits are generated using the following instructions:
IQ=_pack2(C1,C1ˆ((C2&0xAA)|(C2&0xAA)>>1));
IQ=_shfl(IQ);
IQ=_bitr(IQ);
I and Q are interleaved to make a 16 bit value. The best performance achievable is 2.66 codes per cycle. This is a computational load of 1.44 MHz per channel. Without this technique and the instruction level support of the TMS320C6400 digital signal processor the cost of this operation could be ten times greater, putting a significant limitation on a software implementation.

Fibonacci generators cannot be advanced arbitrarily. However Galois has an equivalent arithmetic representation which is more accessible to software implementation and general purpose hardware. The techniques shown link the two constructs together so the best properties of both can be fully exploited.

The desirable properties of the Fibonacci generator have been made accessible using the feed forward matrix mapping. Once an initial seed is generated it can be advanced by any arbitrary time interval by multiplication by powers of α. This can be further decomposed into a combination of powers of 2. The machine is then advanced by k bits per cycle by a repeated multiplication by α^{k}. The F matrix returns the required Fibonacci state containing the future n bits.

Because there is a fixed mapping for each code, less storage is required than the equivalent matrix technique. Hardware cost is approximately equal in either case for a particular code. However this technique allows the same hardware to be used for any number of codes. The storage requirements for the general case are of the order N where as the power method is of the order N³. Galois field multipliers are very small and compact and of the order of logN*N² gates.

The following is an example of the generator equations and matrices when using this invention as an IS95 long code generator. The Galois generator equation is:
G(X)=X⁴²+X³⁵+X³³+X³¹+X²⁷+X²⁶+X²⁵+X²²+X²¹+X¹⁹+X¹⁸+X¹⁷+X¹⁶+X¹⁰+X⁷+X⁶+X⁵+X³+X²+X¹+1 (38)
Feed forward matrix to restore the above to the Fibonacci format is:

$$F = [ \begin{matrix}1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 1 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 1 & 1 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 1 & 1 & 1 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 1 & 1 & 1 & 1 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 1 & 1 & 1 & 1 & 1 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 0 & 1 & 1 & 1 & 1 & 1 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 1 & 0 & 1 & 1 & 1 & 1 & 1 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 \\ 1 & 0 & 1 & 0 & 1 & 1 & 1 & 1 & 1 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 \\ 0 & 1 & 0 & 1 & 0 & 1 & 1 & 1 & 1 & 1 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 \\ 1 & 0 & 1 & 0 & 1 & 0 & 1 & 1 & 1 & 1 & 1 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 \\ 1 & 1 & 0 & 1 & 0 & 1 & 0 & 1 & 1 & 1 & 1 & 1 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 \\ 1 & 1 & 1 & 0 & 1 & 0 & 1 & 0 & 1 & 1 & 1 & 1 & 1 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 \\ 1 & 1 & 1 & 1 & 0 & 1 & 0 & 1 & 0 & 1 & 1 & 1 & 1 & 1 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 \\ 1 & 1 & 1 & 1 & 1 & 0 & 1 & 0 & 1 & 0 & 1 & 1 & 1 & 1 & 1 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 \\ 1 & 1 & 1 & 1 & 1 & 1 & 0 & 1 & 0 & 1 & 0 & 1 & 1 & 1 & 1 & 1 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 \\ 0 & 1 & 1 & 1 & 1 & 1 & 1 & 0 & 1 & 0 & 1 & 0 & 1 & 1 & 1 & 1 & 1 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 \\ 0 & 0 & 1 & 1 & 1 & 1 & 1 & 1 & 0 & 1 & 0 & 1 & 0 & 1 & 1 & 1 & 1 & 1 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 \\ 0 & 0 & 0 & 1 & 1 & 1 & 1 & 1 & 1 & 0 & 1 & 0 & 1 & 0 & 1 & 1 & 1 & 1 & 1 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 \\ 0 & 0 & 0 & 0 & 1 & 1 & 1 & 1 & 1 & 1 & 0 & 1 & 0 & 1 & 0 & 1 & 1 & 1 & 1 & 1 & 0 & 0 & 1 & 0 & 1 & 0 & 1 & 0 & 0 & 0 & 0 & 0 & 0 & 1 & 0 & 0 & 0 & 0 & 0 & 0 & 0 & 0 \\ 1 & 0 & 0 & 0 & 0 & 1 & 1 & 1 & 1 & 1 & 1 & 0 & 1 & 0 & 1 & 0 & 1 & 1 & 1 & 1 & 1 & 0 & 0 & 1 & 0 & 1 & 0 & 1 & 0 & 0 & 0 & 0 & 0 & 0 & 1 & 0 & 0 & 0 & 0 & 0 & 0 & 0 \\ 0 & 1 & 0 & 0 & 0 & 0 & 1 & 1 & 1 & 1 & 1 & 1 & 0 & 1 & 0 & 1 & 0 & 1 & 1 & 1 & 1 & 1 & 0 & 0 & 1 & 0 & 1 & 0 & 1 & 0 & 0 & 0 & 0 & 0 & 0 & 1 & 0 & 0 & 0 & 0 & 0 & 0 \\ 0 & 0 & 1 & 0 & 0 & 0 & 0 & 1 & 1 & 1 & 1 & 1 & 1 & 0 & 1 & 0 & 1 & 0 & 1 & 1 & 1 & 1 & 1 & 0 & 0 & 1 & 0 & 1 & 0 & 1 & 0 & 0 & 0 & 0 & 0 & 0 & 1 & 0 & 0 & 0 & 0 & 0 \\ 1 & 0 & 0 & 1 & 0 & 0 & 0 & 0 & 1 & 1 & 1 & 1 & 1 & 1 & 0 & 1 & 0 & 1 & 0 & 1 & 1 & 1 & 1 & 1 & 0 & 0 & 1 & 0 & 1 & 0 & 1 & 0 & 0 & 0 & 0 & 0 & 0 & 1 & 0 & 0 & 0 & 0 \\ 1 & 1 & 0 & 0 & 1 & 0 & 0 & 0 & 0 & 1 & 1 & 1 & 1 & 1 & 1 & 0 & 1 & 0 & 1 & 0 & 1 & 1 & 1 & 1 & 1 & 0 & 0 & 1 & 0 & 1 & 0 & 1 & 0 & 0 & 0 & 0 & 0 & 0 & 1 & 0 & 0 & 0 \\ 1 & 1 & 1 & 0 & 0 & 1 & 0 & 0 & 0 & 0 & 1 & 1 & 1 & 1 & 1 & 1 & 0 & 1 & 0 & 1 & 0 & 1 & 1 & 1 & 1 & 1 & 0 & 0 & 1 & 0 & 1 & 0 & 1 & 0 & 0 & 0 & 0 & 0 & 0 & 1 & 0 & 0 \\ 1 & 1 & 1 & 1 & 0 & 0 & 1 & 0 & 0 & 0 & 0 & 1 & 1 & 1 & 1 & 1 & 1 & 0 & 1 & 0 & 1 & 0 & 1 & 1 & 1 & 1 & 1 & 0 & 0 & 1 & 0 & 1 & 0 & 1 & 0 & 0 & 0 & 0 & 0 & 0 & 1 & 0 \\ 1 & 1 & 1 & 1 & 1 & 0 & 0 & 1 & 0 & 0 & 0 & 0 & 1 & 1 & 1 & 1 & 1 & 1 & 0 & 1 & 0 & 1 & 0 & 1 & 1 & 1 & 1 & 1 & 0 & 0 & 1 & 0 & 1 & 0 & 1 & 0 & 0 & 0 & 0 & 0 & 0 & 1\end{matrix} ]$$

The transformed inverse feed forward matrix to convert from Fibonacci form to Galois form is:

$$F = [ \begin{matrix}1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 0 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 1 & 0 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 1 & 1 & 0 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 1 & 1 & 1 & 0 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 1 & 1 & 1 & 0 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 0 & 0 & 1 & 1 & 1 & 0 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 1 & 0 & 0 & 1 & 1 & 1 & 0 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 \\ 0 & 1 & 1 & 0 & 0 & 1 & 1 & 1 & 0 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 \\ 1 & 0 & 1 & 1 & 0 & 0 & 1 & 1 & 1 & 0 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 & 0 \\ 1 & 1 & 0 & 1 & 1 & 0 & 0 & 1 & 1 & 1 & 0 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 & 0 \\ 1 & 1 & 1 & 0 & 1 & 1 & 0 & 0 & 1 & 1 & 1 & 0 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 0 \\ 1 & 1 & 1 & 1 & 0 & 1 & 1 & 0 & 0 & 1 & 1 & 1 & 0 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 & 0 \\ 0 & 1 & 1 & 1 & 1 & 0 & 1 & 1 & 0 & 0 & 1 & 1 & 1 & 0 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 & 0 \\ 0 & 0 & 1 & 1 & 1 & 1 & 0 & 1 & 1 & 0 & 0 & 1 & 1 & 1 & 0 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 & 0 \\ 0 & 0 & 0 & 1 & 1 & 1 & 1 & 0 & 1 & 1 & 0 & 0 & 1 & 1 & 1 & 0 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 & 0 \\ 0 & 0 & 0 & 0 & 1 & 1 & 1 & 1 & 0 & 1 & 1 & 0 & 0 & 1 & 1 & 1 & 0 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 & 0 \\ 0 & 0 & 0 & 0 & 0 & 1 & 1 & 1 & 1 & 0 & 1 & 1 & 0 & 0 & 1 & 1 & 1 & 0 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 & 0 \\ 1 & 0 & 0 & 0 & 0 & 0 & 1 & 1 & 1 & 1 & 0 & 1 & 1 & 0 & 0 & 1 & 1 & 1 & 0 & 0 & 0 & 1 & 0 & 1 & 0 & 1 & 0 & 0 & 0 & 0 & 0 & 0 & 1 & 0 & 0 & 0 & 0 & 0 & 0 & 0 & 0 & 0 \\ 0 & 1 & 0 & 0 & 0 & 0 & 0 & 1 & 1 & 1 & 1 & 0 & 1 & 1 & 0 & 0 & 1 & 1 & 1 & 0 & 0 & 0 & 1 & 0 & 1 & 0 & 1 & 0 & 0 & 0 & 0 & 0 & 0 & 1 & 0 & 0 & 0 & 0 & 0 & 0 & 0 & 0 \\ 0 & 0 & 1 & 0 & 0 & 0 & 0 & 0 & 1 & 1 & 1 & 1 & 0 & 1 & 1 & 0 & 0 & 1 & 1 & 1 & 0 & 0 & 0 & 1 & 0 & 1 & 0 & 1 & 0 & 0 & 0 & 0 & 0 & 0 & 1 & 0 & 0 & 0 & 0 & 0 & 0 & 0 \\ 1 & 0 & 0 & 1 & 0 & 0 & 0 & 0 & 0 & 1 & 1 & 1 & 1 & 0 & 1 & 1 & 0 & 0 & 1 & 1 & 1 & 0 & 0 & 0 & 1 & 0 & 1 & 0 & 1 & 0 & 0 & 0 & 0 & 0 & 0 & 1 & 0 & 0 & 0 & 0 & 0 & 0 \\ 1 & 1 & 0 & 0 & 1 & 0 & 0 & 0 & 0 & 0 & 1 & 1 & 1 & 1 & 0 & 1 & 1 & 0 & 0 & 1 & 1 & 1 & 0 & 0 & 0 & 1 & 0 & 1 & 0 & 1 & 0 & 0 & 0 & 0 & 0 & 0 & 1 & 0 & 0 & 0 & 0 & 0 \\ 1 & 1 & 1 & 0 & 0 & 1 & 0 & 0 & 0 & 0 & 0 & 1 & 1 & 1 & 1 & 0 & 1 & 1 & 0 & 0 & 1 & 1 & 1 & 0 & 0 & 0 & 1 & 0 & 1 & 0 & 1 & 0 & 0 & 0 & 0 & 0 & 0 & 1 & 0 & 0 & 0 & 0 \\ 0 & 1 & 1 & 1 & 0 & 0 & 1 & 0 & 0 & 0 & 0 & 0 & 1 & 1 & 1 & 1 & 0 & 1 & 1 & 0 & 0 & 1 & 1 & 1 & 0 & 0 & 0 & 1 & 0 & 1 & 0 & 1 & 0 & 0 & 0 & 0 & 0 & 0 & 1 & 0 & 0 & 0 \\ 1 & 0 & 1 & 1 & 1 & 0 & 0 & 1 & 0 & 0 & 0 & 0 & 0 & 1 & 1 & 1 & 1 & 0 & 1 & 1 & 0 & 0 & 1 & 1 & 1 & 0 & 0 & 0 & 1 & 0 & 1 & 0 & 1 & 0 & 0 & 0 & 0 & 0 & 0 & 1 & 0 & 0 \\ 1 & 1 & 0 & 1 & 1 & 1 & 0 & 0 & 1 & 0 & 0 & 0 & 0 & 0 & 1 & 1 & 1 & 1 & 0 & 1 & 1 & 0 & 0 & 1 & 1 & 1 & 0 & 0 & 0 & 1 & 0 & 1 & 0 & 1 & 0 & 0 & 0 & 0 & 0 & 0 & 1 & 0 \\ 1 & 1 & 1 & 0 & 1 & 1 & 1 & 0 & 0 & 1 & 0 & 0 & 0 & 0 & 0 & 1 & 1 & 1 & 1 & 0 & 1 & 1 & 0 & 0 & 1 & 1 & 1 & 0 & 0 & 0 & 1 & 0 & 1 & 0 & 1 & 0 & 0 & 0 & 0 & 0 & 0 & 1\end{matrix} ]$$

Elements selected by the mask for equivalent initial state offset is:

TABLE 4

| Mask Value 0-20 | Mask Value 21-41 |
|---|---|
| 0x00000000, 0x00000001 | 0x00000000, 0x00205473 |
| 0x00000000, 0x00000002 | 0x00000000, 0x0040a8e6 |
| 0x00000000, 0x00000004 | 0x00000000, 0x008151cd |
| 0x00000000, 0x00000008 | 0x00000000, 0x0102a39b |
| 0x00000000, 0x00000010 | 0x00000000, 0x02054737 |
| 0x00000000, 0x00000020 | 0x00000000, 0x040a8e6f |
| 0x00000000, 0x00000040 | 0x00000000, 0x08151cde |
| 0x00000000, 0x00000081 | 0x00000000, 0x102a39bc |
| 0x00000000, 0x00000102 | 0x00000000, 0x20547378 |
| 0x00000000, 0x00000205 | 0x00000000, 0x40a8e6f0 |
| 0x00000000, 0x0000040a | 0x00000000, 0x8151cde0 |
| 0x00000000, 0x00000815 | 0x00000001, 0x02a39bc1 |
| 0x00000000, 0x0000102a | 0x00000002, 0x05473782 |
| 0x00000000, 0x00002054 | 0x00000004, 0x0a8e6f04 |
| 0x00000000, 0x000040a8 | 0x00000008, 0x151cde09 |
| 0x00000000, 0x00008151 | 0x00000010, 0x2a39bc13 |
| 0x00000000, 0x000102a3 | 0x00000020, 0x54737827 |
| 0x00000000, 0x00020547 | 0x00000040, 0xa8e6f04e |
| 0x00000000, 0x00040a8e | 0x00000081, 0x51cde09d |
| 0x00000000, 0x0008151c | 0x00000102, 0xa39bc13b |
| 0x00000000, 0x00102a39 | 0x00000205, 0x47378277 |

The tap weight vector for multiplication by powers of α⁻¹ is:

$$TVM = [ \begin{matrix}0 & 0 & 0 & 0 & 0 & 0 & 1 & 0 & 1 & 0 & 1 & 0 & 0 & 0 & 1 & 1 & 1 & 0 & 0 & 1 & 1 & 0 & 1 & 1 & 1 & 1 & 0 & 0 & 0 & 0 & 0 & 1 & 0 & 0 & 1 & 1 & 1 & 0 & 1 & 1 & 1 & 1 \\ 0 & 0 & 0 & 0 & 0 & 1 & 0 & 1 & 0 & 1 & 0 & 0 & 0 & 1 & 1 & 1 & 0 & 0 & 1 & 1 & 0 & 1 & 1 & 1 & 1 & 0 & 0 & 0 & 0 & 0 & 1 & 0 & 0 & 1 & 1 & 1 & 0 & 1 & 1 & 1 & 1 & 0 \\ 0 & 0 & 0 & 0 & 1 & 0 & 1 & 0 & 1 & 0 & 0 & 0 & 1 & 1 & 1 & 0 & 0 & 1 & 1 & 0 & 1 & 1 & 1 & 1 & 0 & 0 & 0 & 0 & 0 & 1 & 0 & 0 & 1 & 1 & 1 & 0 & 1 & 1 & 1 & 1 & 0 & 0 \\ 0 & 0 & 0 & 1 & 0 & 1 & 0 & 1 & 0 & 0 & 0 & 1 & 1 & 1 & 0 & 0 & 1 & 1 & 0 & 1 & 1 & 1 & 1 & 0 & 0 & 0 & 0 & 0 & 1 & 0 & 0 & 1 & 1 & 1 & 0 & 1 & 1 & 1 & 1 & 0 & 0 & 0 \\ 0 & 0 & 1 & 0 & 1 & 0 & 1 & 0 & 0 & 0 & 1 & 1 & 1 & 0 & 0 & 1 & 1 & 0 & 1 & 1 & 1 & 1 & 0 & 0 & 0 & 0 & 0 & 1 & 0 & 0 & 1 & 1 & 1 & 0 & 1 & 1 & 1 & 1 & 0 & 0 & 0 & 0 \\ 0 & 1 & 0 & 1 & 0 & 1 & 0 & 0 & 0 & 1 & 1 & 1 & 0 & 0 & 1 & 1 & 0 & 1 & 1 & 1 & 1 & 0 & 0 & 0 & 0 & 0 & 1 & 0 & 0 & 1 & 1 & 1 & 0 & 1 & 1 & 1 & 1 & 0 & 0 & 0 & 0 & 0 \\ 1 & 0 & 1 & 0 & 1 & 0 & 0 & 0 & 1 & 1 & 1 & 0 & 0 & 1 & 1 & 0 & 1 & 1 & 1 & 1 & 0 & 0 & 0 & 0 & 0 & 1 & 0 & 0 & 1 & 1 & 1 & 0 & 1 & 1 & 1 & 1 & 0 & 0 & 0 & 0 & 0 & 0 \\ 0 & 1 & 0 & 1 & 0 & 0 & 0 & 1 & 1 & 1 & 0 & 0 & 1 & 1 & 0 & 1 & 1 & 1 & 1 & 0 & 0 & 0 & 0 & 0 & 1 & 0 & 0 & 1 & 1 & 1 & 0 & 1 & 1 & 1 & 1 & 0 & 0 & 0 & 0 & 0 & 0 & 0 \\ 1 & 0 & 1 & 0 & 0 & 0 & 1 & 1 & 1 & 0 & 0 & 1 & 1 & 0 & 1 & 1 & 1 & 1 & 0 & 0 & 0 & 0 & 0 & 1 & 0 & 0 & 1 & 1 & 1 & 0 & 1 & 1 & 1 & 1 & 0 & 0 & 0 & 0 & 0 & 0 & 0 & 0 \\ 0 & 1 & 0 & 0 & 0 & 1 & 1 & 1 & 0 & 0 & 1 & 1 & 0 & 1 & 1 & 1 & 1 & 0 & 0 & 0 & 0 & 0 & 1 & 0 & 0 & 1 & 1 & 1 & 0 & 1 & 1 & 1 & 1 & 0 & 0 & 0 & 0 & 0 & 0 & 0 & 0 & 0 \\ 1 & 0 & 0 & 0 & 1 & 1 & 1 & 0 & 0 & 1 & 1 & 0 & 1 & 1 & 1 & 1 & 0 & 0 & 0 & 0 & 0 & 1 & 0 & 0 & 1 & 1 & 1 & 0 & 1 & 1 & 1 & 1 & 0 & 0 & 0 & 0 & 0 & 0 & 0 & 0 & 0 & 0 \\ 0 & 0 & 0 & 1 & 1 & 1 & 0 & 0 & 1 & 1 & 0 & 1 & 1 & 1 & 1 & 0 & 0 & 0 & 0 & 0 & 1 & 0 & 0 & 1 & 1 & 1 & 0 & 1 & 1 & 1 & 1 & 0 & 0 & 0 & 0 & 0 & 0 & 0 & 0 & 0 & 0 & 0 \\ 0 & 0 & 1 & 1 & 1 & 0 & 0 & 1 & 1 & 0 & 1 & 1 & 1 & 1 & 0 & 0 & 0 & 0 & 0 & 1 & 0 & 0 & 1 & 1 & 1 & 0 & 1 & 1 & 1 & 1 & 0 & 0 & 0 & 0 & 0 & 0 & 0 & 0 & 0 & 0 & 0 & 0 \\ 0 & 1 & 1 & 1 & 0 & 0 & 1 & 1 & 0 & 1 & 1 & 1 & 1 & 0 & 0 & 0 & 0 & 0 & 1 & 0 & 0 & 1 & 1 & 1 & 0 & 1 & 1 & 1 & 1 & 0 & 0 & 0 & 0 & 0 & 0 & 0 & 0 & 0 & 0 & 0 & 0 & 0 \\ 1 & 1 & 1 & 0 & 0 & 1 & 1 & 0 & 1 & 1 & 1 & 1 & 0 & 0 & 0 & 0 & 0 & 1 & 0 & 0 & 1 & 1 & 1 & 0 & 1 & 1 & 1 & 1 & 0 & 0 & 0 & 0 & 0 & 0 & 0 & 0 & 0 & 0 & 0 & 0 & 0 & 0 \\ 1 & 1 & 0 & 0 & 1 & 1 & 0 & 1 & 1 & 1 & 1 & 0 & 0 & 0 & 0 & 0 & 1 & 0 & 0 & 1 & 1 & 1 & 0 & 1 & 1 & 1 & 1 & 0 & 0 & 0 & 0 & 0 & 0 & 0 & 0 & 0 & 0 & 0 & 0 & 0 & 0 & 0 \\ 1 & 0 & 0 & 1 & 1 & 0 & 1 & 1 & 1 & 1 & 0 & 0 & 0 & 0 & 0 & 1 & 0 & 0 & 1 & 1 & 1 & 0 & 1 & 1 & 1 & 1 & 0 & 0 & 0 & 0 & 0 & 0 & 0 & 0 & 0 & 0 & 0 & 0 & 0 & 0 & 0 & 0 \\ 0 & 0 & 1 & 1 & 0 & 1 & 1 & 1 & 1 & 0 & 0 & 0 & 0 & 0 & 1 & 0 & 0 & 1 & 1 & 1 & 0 & 1 & 1 & 1 & 1 & 0 & 0 & 0 & 0 & 0 & 0 & 0 & 0 & 0 & 0 & 0 & 0 & 0 & 0 & 0 & 0 & 0 \\ 0 & 1 & 1 & 0 & 1 & 1 & 1 & 1 & 0 & 0 & 0 & 0 & 0 & 1 & 0 & 0 & 1 & 1 & 1 & 0 & 1 & 1 & 1 & 1 & 0 & 0 & 0 & 0 & 0 & 0 & 0 & 0 & 0 & 0 & 0 & 0 & 0 & 0 & 0 & 0 & 0 & 0 \\ 1 & 1 & 0 & 1 & 1 & 1 & 1 & 0 & 0 & 0 & 0 & 0 & 1 & 0 & 0 & 1 & 1 & 1 & 0 & 1 & 1 & 1 & 1 & 0 & 0 & 0 & 0 & 0 & 0 & 0 & 0 & 0 & 0 & 0 & 0 & 0 & 0 & 0 & 0 & 0 & 0 & 0 \\ 1 & 0 & 1 & 1 & 1 & 1 & 0 & 0 & 0 & 0 & 0 & 1 & 0 & 0 & 1 & 1 & 1 & 0 & 1 & 1 & 1 & 1 & 0 & 0 & 0 & 0 & 0 & 0 & 0 & 0 & 0 & 0 & 0 & 0 & 0 & 0 & 0 & 0 & 0 & 0 & 0 & 0 \\ 0 & 1 & 1 & 1 & 1 & 0 & 0 & 0 & 0 & 0 & 1 & 0 & 0 & 1 & 1 & 1 & 0 & 1 & 1 & 1 & 1 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 1 & 1 & 1 & 0 & 0 & 0 & 0 & 0 & 1 & 0 & 0 & 1 & 1 & 1 & 0 & 1 & 1 & 1 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 1 & 1 & 0 & 0 & 0 & 0 & 0 & 1 & 0 & 0 & 1 & 1 & 1 & 0 & 1 & 1 & 1 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 1 & 0 & 0 & 0 & 0 & 0 & 1 & 0 & 0 & 1 & 1 & 1 & 0 & 1 & 1 & 1 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 0 & 0 & 0 & 0 & 0 & 1 & 0 & 0 & 1 & 1 & 1 & 0 & 1 & 1 & 1 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 0 & 1 & 0 & 0 & 1 & 1 & 1 & 0 & 1 & 1 & 1 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 0 & 1 & 0 & 0 & 1 & 1 & 1 & 0 & 1 & 1 & 1 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 0 & 1 & 0 & 0 & 1 & 1 & 1 & 0 & 1 & 1 & 1 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 1 & 0 & 0 & 1 & 1 & 1 & 0 & 1 & 1 & 1 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 1 & 0 & 0 & 1 & 1 & 1 & 0 & 1 & 1 & 1 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 0 & 0 & 1 & 1 & 1 & 0 & 1 & 1 & 1 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 0 & 1 & 1 & 1 & 0 & 1 & 1 & 1 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 1 & 1 & 1 & 0 & 1 & 1 & 1 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 1 & 1 & 0 & 1 & 1 & 1 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 1 & 0 & 1 & 1 & 1 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 0 & 1 & 1 & 1 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 0 & 1 & 1 & 1 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 1 & 1 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 1 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 \\ 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 0\end{matrix} ]$$

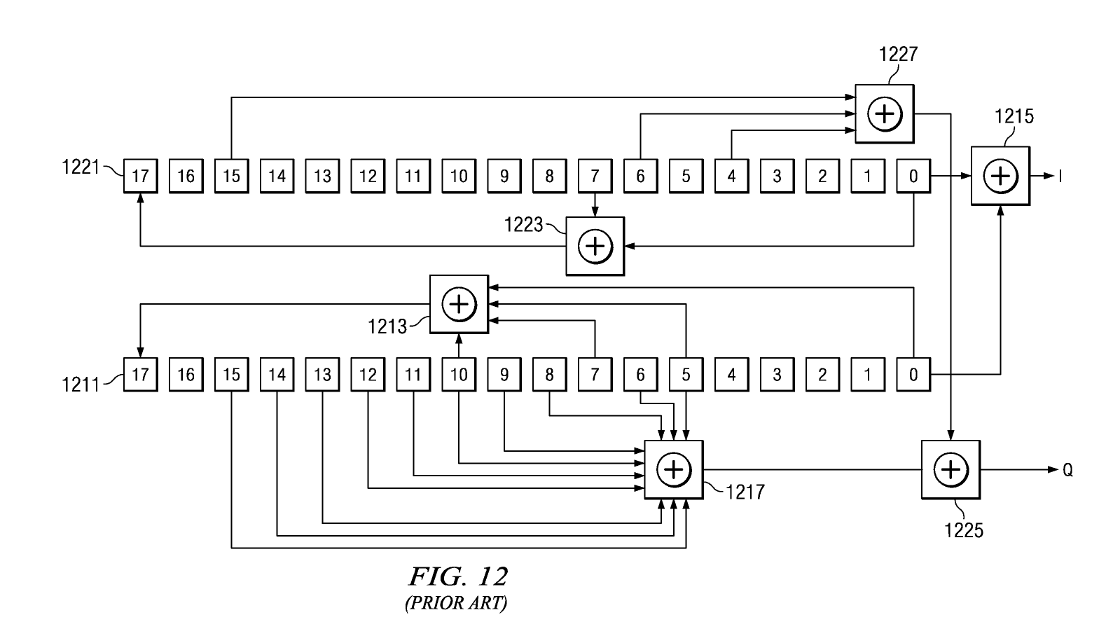

FIG. 12 illustrates an example of a 3GPP downlink scramble code generator. FIG. 12 illustrates generator X shift register 1211 and generator Y shift register 1221.

The 2 generators are then summed together modulo 2 in summer 1215. This forms the in-phase part of the sequence. The quadrature part is the same sequence delayed via summers 1217 and 1227. Summer 1225 modulo 2 sums these delayed signals for the quadrature output. The generator equation G(X)=X¹⁸+X¹⁰+X⁷+X⁵+1 is provided by summer 1213. The transposed conversion matrices the uplink code generator of the form for the generator equation G(X)=X¹⁸+X¹⁰+X⁷+X⁵+1 are:

$$F = [ \begin{matrix}1 & 0 & 0 & 0 & 0 & 0 & 0 & 0 & 0 & 0 & 0 & 0 & 0 & 0 & 0 & 0 & 0 & 0 \\ 0 & 1 & 0 & 0 & 0 & 0 & 0 & 0 & 0 & 0 & 0 & 0 & 0 & 0 & 0 & 0 & 0 & 0 \\ 0 & 0 & 1 & 0 & 0 & 0 & 0 & 0 & 0 & 0 & 0 & 0 & 0 & 0 & 0 & 0 & 0 & 0 \\ 0 & 0 & 0 & 1 & 0 & 0 & 0 & 0 & 0 & 0 & 0 & 0 & 0 & 0 & 0 & 0 & 0 & 0 \\ 0 & 0 & 0 & 0 & 1 & 0 & 0 & 0 & 0 & 0 & 0 & 0 & 0 & 0 & 0 & 0 & 0 & 0 \\ 0 & 0 & 0 & 0 & 0 & 1 & 0 & 0 & 0 & 0 & 0 & 0 & 0 & 0 & 0 & 0 & 0 & 0 \\ 0 & 0 & 0 & 0 & 0 & 0 & 1 & 0 & 0 & 0 & 0 & 0 & 0 & 0 & 0 & 0 & 0 & 0 \\ 0 & 0 & 0 & 0 & 0 & 0 & 0 & 1 & 0 & 0 & 0 & 0 & 0 & 0 & 0 & 0 & 0 & 0 \\ 1 & 0 & 0 & 0 & 0 & 0 & 0 & 0 & 1 & 0 & 0 & 0 & 0 & 0 & 0 & 0 & 0 & 0 \\ 0 & 1 & 0 & 0 & 0 & 0 & 0 & 0 & 0 & 1 & 0 & 0 & 0 & 0 & 0 & 0 & 0 & 0 \\ 0 & 0 & 1 & 0 & 0 & 0 & 0 & 0 & 0 & 0 & 1 & 0 & 0 & 0 & 0 & 0 & 0 & 0 \\ 1 & 0 & 0 & 1 & 0 & 0 & 0 & 0 & 0 & 0 & 0 & 1 & 0 & 0 & 0 & 0 & 0 & 0 \\ 0 & 1 & 0 & 0 & 1 & 0 & 0 & 0 & 0 & 0 & 0 & 0 & 1 & 0 & 0 & 0 & 0 & 0 \\ 1 & 0 & 1 & 0 & 0 & 1 & 0 & 0 & 0 & 0 & 0 & 0 & 0 & 1 & 0 & 0 & 0 & 0 \\ 0 & 1 & 0 & 1 & 0 & 0 & 1 & 0 & 0 & 0 & 0 & 0 & 0 & 0 & 1 & 0 & 0 & 0 \\ 0 & 0 & 1 & 0 & 1 & 0 & 0 & 1 & 0 & 0 & 0 & 0 & 0 & 0 & 0 & 1 & 0 & 0 \\ 1 & 0 & 0 & 1 & 0 & 1 & 0 & 0 & 1 & 0 & 0 & 0 & 0 & 0 & 0 & 0 & 1 & 0 \\ 0 & 1 & 0 & 0 & 1 & 0 & 1 & 0 & 0 & 1 & 0 & 0 & 0 & 0 & 0 & 0 & 0 & 1\end{matrix} ]$$

$${F}^{- 1} = [ \begin{matrix}1 & 0 & 0 & 0 & 0 & 0 & 0 & 0 & 0 & 0 & 0 & 0 & 0 & 0 & 0 & 0 & 0 & 0 \\ 0 & 1 & 0 & 0 & 0 & 0 & 0 & 0 & 0 & 0 & 0 & 0 & 0 & 0 & 0 & 0 & 0 & 0 \\ 0 & 0 & 1 & 0 & 0 & 0 & 0 & 0 & 0 & 0 & 0 & 0 & 0 & 0 & 0 & 0 & 0 & 0 \\ 0 & 0 & 0 & 1 & 0 & 0 & 0 & 0 & 0 & 0 & 0 & 0 & 0 & 0 & 0 & 0 & 0 & 0 \\ 0 & 0 & 0 & 0 & 1 & 0 & 0 & 0 & 0 & 0 & 0 & 0 & 0 & 0 & 0 & 0 & 0 & 0 \\ 0 & 0 & 0 & 0 & 0 & 1 & 0 & 0 & 0 & 0 & 0 & 0 & 0 & 0 & 0 & 0 & 0 & 0 \\ 0 & 0 & 0 & 0 & 0 & 0 & 1 & 0 & 0 & 0 & 0 & 0 & 0 & 0 & 0 & 0 & 0 & 0 \\ 0 & 0 & 0 & 0 & 0 & 0 & 0 & 1 & 0 & 0 & 0 & 0 & 0 & 0 & 0 & 0 & 0 & 0 \\ 1 & 0 & 0 & 0 & 0 & 0 & 0 & 0 & 1 & 0 & 0 & 0 & 0 & 0 & 0 & 0 & 0 & 0 \\ 0 & 1 & 0 & 0 & 0 & 0 & 0 & 0 & 0 & 1 & 0 & 0 & 0 & 0 & 0 & 0 & 0 & 0 \\ 0 & 0 & 1 & 0 & 0 & 0 & 0 & 0 & 0 & 0 & 1 & 0 & 0 & 0 & 0 & 0 & 0 & 0 \\ 1 & 0 & 0 & 1 & 0 & 0 & 0 & 0 & 0 & 0 & 0 & 1 & 0 & 0 & 0 & 0 & 0 & 0 \\ 0 & 1 & 0 & 0 & 1 & 0 & 0 & 0 & 0 & 0 & 0 & 0 & 1 & 0 & 0 & 0 & 0 & 0 \\ 1 & 0 & 1 & 0 & 0 & 1 & 0 & 0 & 0 & 0 & 0 & 0 & 0 & 1 & 0 & 0 & 0 & 0 \\ 0 & 1 & 0 & 1 & 0 & 0 & 1 & 0 & 0 & 0 & 0 & 0 & 0 & 0 & 1 & 0 & 0 & 0 \\ 0 & 0 & 1 & 0 & 1 & 0 & 0 & 1 & 0 & 0 & 0 & 0 & 0 & 0 & 0 & 1 & 0 & 0 \\ 0 & 0 & 0 & 1 & 0 & 1 & 0 & 0 & 1 & 0 & 0 & 0 & 0 & 0 & 0 & 0 & 1 & 0 \\ 0 & 0 & 0 & 0 & 1 & 0 & 1 & 0 & 0 & 1 & 0 & 0 & 0 & 0 & 0 & 0 & 0 & 1\end{matrix} ]$$

The delay coefficient is 0x0000FF60. The transposed conversion self inverse matrix for f(x)=X¹⁸+X⁷+1 downlink code 2 produced via summer 1223 is:

$$\begin{matrix}{F}^{- 1} = F \\ = [ \begin{matrix}1 & 0 & 0 & 0 & 0 & 0 & 0 & 0 & 0 & 0 & 0 & 0 & 0 & 0 & 0 & 0 & 0 & 0 \\ 0 & 1 & 0 & 0 & 0 & 0 & 0 & 0 & 0 & 0 & 0 & 0 & 0 & 0 & 0 & 0 & 0 & 0 \\ 0 & 0 & 1 & 0 & 0 & 0 & 0 & 0 & 0 & 0 & 0 & 0 & 0 & 0 & 0 & 0 & 0 & 0 \\ 0 & 0 & 0 & 1 & 0 & 0 & 0 & 0 & 0 & 0 & 0 & 0 & 0 & 0 & 0 & 0 & 0 & 0 \\ 0 & 0 & 0 & 0 & 1 & 0 & 0 & 0 & 0 & 0 & 0 & 0 & 0 & 0 & 0 & 0 & 0 & 0 \\ 0 & 0 & 0 & 0 & 0 & 1 & 0 & 0 & 0 & 0 & 0 & 0 & 0 & 0 & 0 & 0 & 0 & 0 \\ 0 & 0 & 0 & 0 & 0 & 0 & 1 & 0 & 0 & 0 & 0 & 0 & 0 & 0 & 0 & 0 & 0 & 0 \\ 0 & 0 & 0 & 0 & 0 & 0 & 0 & 1 & 0 & 0 & 0 & 0 & 0 & 0 & 0 & 0 & 0 & 0 \\ 0 & 0 & 0 & 0 & 0 & 0 & 0 & 0 & 1 & 0 & 0 & 0 & 0 & 0 & 0 & 0 & 0 & 0 \\ 0 & 0 & 0 & 0 & 0 & 0 & 0 & 0 & 0 & 1 & 0 & 0 & 0 & 0 & 0 & 0 & 0 & 0 \\ 0 & 0 & 0 & 0 & 0 & 0 & 0 & 0 & 0 & 0 & 1 & 0 & 0 & 0 & 0 & 0 & 0 & 0 \\ 1 & 0 & 0 & 0 & 0 & 0 & 0 & 0 & 0 & 0 & 0 & 1 & 0 & 0 & 0 & 0 & 0 & 0 \\ 0 & 1 & 0 & 0 & 0 & 0 & 0 & 0 & 0 & 0 & 0 & 0 & 1 & 0 & 0 & 0 & 0 & 0 \\ 0 & 0 & 1 & 0 & 0 & 0 & 0 & 0 & 0 & 0 & 0 & 0 & 0 & 1 & 0 & 0 & 0 & 0 \\ 0 & 0 & 0 & 1 & 0 & 0 & 0 & 0 & 0 & 0 & 0 & 0 & 0 & 0 & 1 & 0 & 0 & 0 \\ 0 & 0 & 0 & 0 & 1 & 0 & 0 & 0 & 0 & 0 & 0 & 0 & 0 & 0 & 0 & 1 & 0 & 0 \\ 0 & 0 & 0 & 0 & 0 & 1 & 0 & 0 & 0 & 0 & 0 & 0 & 0 & 0 & 0 & 0 & 1 & 0 \\ 0 & 0 & 0 & 0 & 0 & 1 & 0 & 0 & 0 & 0 & 0 & 0 & 0 & 0 & 0 & 0 & 0 & 1\end{matrix} ]\end{matrix}$$

The delay coefficient is 0x0008050 for an arbitrary delay of αⁿ=0 to 2¹⁸−2.

The LFSR structures described above are known as gold codes. A fundamental property of these sequences is that any linear combination of time delayed sequences of these will merely generate another time delayed sequence. This is an observation of the property in Galois field arithmetic. It is equivalent to the fact that a sum of numbers in GF(2^{N}) being a number also in GF(2^{N}). Because the elements of the multiplicative group also form an additive group, a sequence can be shifted in time by multiplying it by a power of α. This multiplication can also be achieved by adding the correct value as shown in equation (39):

$${α}^{j} = {\sum }_{i = 0}^{n} {α}^{{k}_{i}} \qquad ( 39 )$$

The additive group is not as well behaved as the multiplicative group, but it can be used to generate very large shift amounts to sequences with just additive combinations of some very small time shifts. This principle is harnessed in converting the Galois sequence to the Fibonacci one. The Galois state sequence in Table 1 is a set of the parallel gold sequences just like the Fibonacci sequence. Each column in the Galois table is a time shifted version of the first.

FIG. 13 illustrates a method of use of this invention. The digital signal processor described in conjunction with FIGS. 1 to 4, 8 and 9 can be programmed to practice this method. The method starts at start block 1301. Block 1302 sets the Fibonacci initial state vector S and the tap weight vector T. These vectors may be fixed according to the particular application or they may be determined at run time by the digital signal processor. Block 1303 converts this Fibonacci form into the corresponding Galois form according to the teachings of this application. Block 1304 performs Galois field arithmetic on the resulting Galois form of the linear feedback shift register. As detailed above many useful transforms such as time shifts are easier to perform in the Galois form than in the Fibonacci form. Block 1305 converts the Galois form back into the Fibonacci form according to the teachings of this application. Block 1306 uses the resultant pseudo-random number. It is known in the art to use these linear feedback shift register generated pseudo-random numbers for many applications in communications. The process ends at end block 1307. This process may be repeated as needed.

What is claimed is:

1. A method of using a Fibonacci form linear feedback shift register comprising the steps of:
determining an initial state for the Fibonacci form linear feedback shift register;
determining a set of taps for the Fibonacci form linear feedback shift register;
converting the Fibonacci form linear feedback shift register having the determined initial state and set of taps into an equivalent Galois form linear feedback shift register;
altering the Galois form linear feedback shift register state employing Galois field arithmetic;
converting the altered Galois form linear feedback shift register into an equivalent altered Fibonacci form linear feedback shift register;
using a pseudo-random number produced by the altered Fibonacci form linear feedback shift register.

2. The method of claim 1, wherein:
said step of altering the Galois form linear feedback shift register state includes advancing the state of said Galois form linear feedback shift register state one step by Galois field multiplying a current state vector of states of the Galois form linear feedback shift register state by a transition state matrix.

3. The method of claim 2, wherein:
said transition state matrix is
$$[ \begin{matrix}0 & 1 & 0 & 0 & … & 0 \\ 0 & 0 & 1 & 0 & … & 0 \\ 0 & 0 & 0 & 1 & … & 0 \\ ⋮ & ⋮ & ⋮ & ⋮ & ⋰ & ⋮ \\ 0 & 0 & 0 & 0 & … & 1 \\ {g}_{0} & {g}_{1} & {g}_{2} & {g}_{3} & … & {g}_{N - 1}\end{matrix} ]$$
where: g₀, g₁, g₂, g₃ . . . g_{N-1} are the tap weights of the equivalent Galois form linear feedback shift register.

4. The method of claim 1, wherein:
said step of altering the Galois form linear feedback shift register state includes advancing the state of said Galois form linear feedback shift register state a predetermined offset number of steps by Galois field multiplying a current state vector of states of the Galois form linear feedback shift register state by a transition state matrix a corresponding number of times.

5. The method of claim 4, wherein:
said transition state matrix is
$$[ \begin{matrix}0 & 1 & 0 & 0 & … & 0 \\ 0 & 0 & 1 & 0 & … & 0 \\ 0 & 0 & 0 & 1 & … & 0 \\ ⋮ & ⋮ & ⋮ & ⋮ & ⋰ & ⋮ \\ 0 & 0 & 0 & 0 & … & 1 \\ {g}_{0} & {g}_{1} & {g}_{2} & {g}_{3} & … & {g}_{N - 1}\end{matrix} ]$$
where: g₀, g₁, g₂, g₃ . . . g_{N-1} are the tap weights of the equivalent Galois form linear feedback shift register.

6. The method of claim 1, wherein:
said step of altering the Galois form linear feedback shift register state includes advancing the state of said Galois form linear feedback shift register state each of a predetermined offset number of steps by Galois field multiplying a current state vector of states of the Galois form linear feedback shift register state by a transition state matrix a corresponding number of times, thereby generating plural pseudo-noise outputs;
said step of converting the each of the altered Galois form linear feedback shift register into a corresponding equivalent altered Fibonacci form linear feedback shift register; and
said step of using a pseudo-random number includes using the pseudo-number output of each of the equivalent altered Fibonacci form linear feedback shift register.

7. The method of claim 1, wherein:
said step of converting the Galois form linear feedback shift register into an equivalent Fibonacci form linear feedback shift register includes multiplying a state vector of a current state of the Galois form linear feedback shift register by a feed forward matrix.

8. The method of claim 7, wherein:
the feed forward matrix F has the form:
$$F = {\sum }_{i = 0}^{N - 1} {R}^{i} {e}_{0} \cdot {e}_{0}^{T} \cdot {G}^{i}$$
where: e₀ is a vector of the form [0,0,0,0,0 . . . 1]^{T}; R is an up shift matrix of the form
$$[ \begin{matrix}0 & I \\ 0 & 0\end{matrix} ] ;$$
G is an initial generator matrix of the form
$$[ \begin{matrix}0 & 1 \\ I & {g}^{T}\end{matrix} ] ;$$
and T is the tap weight vector of the form
$$[ \begin{matrix}{g}_{0} \\ {g}_{1} \\ ⋮ \\ {g}_{N - 1}\end{matrix} ]$$
where gᵢ is the i-th tap weight.

9. The method of claim 8, wherein:
said step of converting the Fibonacci form linear feedback shift register into an equivalent Galois form linear feedback shift register includes multiplying a state vector of a current state of the Fibonacci form linear feedback shift register by an inverse of the feed forward matrix F⁻¹.

10. The method of claim 9, wherein:
said step of converting the Fibonacci form linear feedback shift register into an equivalent Galois form linear feedback shift register includes the iterative operation of
setting an initial estimate F₀⁻¹ of the inverse feed forward matrix F⁻¹ equal to the feed forward matrix F,
calculating an error E=Fᵢ⁻¹+F+I,
if E does not equal 0, then setting a next estimate Fᵢ₊₁⁻¹ of the inverse feed forward F⁻¹ equal to Fᵢ⁻¹+E, until E equals zero.
